(19) United States
(12) Patent Application Publication
(10) Pub. No.: US 2026/0268859 A1
(43) Pub. Date: Sep. 10, 2026

(54) SCAN CIRCUIT, DISPLAY APPARATUS, AND METHOD OF OPERATING SCAN CIRCUIT

(71) Applicants: Beijing BOE Technology Development Co., Ltd., Beijing (CN); BOE Technology Group Co., Ltd., Beijing (CN)

(72) Inventors: Jianbo Xian, Beijing (CN); Xueguang Hao, Beijing (CN); Jingquan Wang, Beijing (CN); Yong Qiao, Beijing (CN)

(73) Assignees: Beijing BOE Technology Development Co., Ltd., Beijing (CN); BOE Technology Group Co., Ltd., Beijing (CN)

(21) Appl. No.: 19/659,475

(22) Filed: Apr. 27, 2026

Related U.S. Application Data
(63) Continuation of application No. PCT/CN2024/131921, filed on Nov. 14, 2024.

(51) Int. Cl. G09G 3/3266; G09G 3/32; G11C 19/28

(52) U.S. Cl. CPC G09G 3/3266; G09G 3/32; G09G 2300/0819; G09G 2300/0866; G09G 2310/0267; G09G 2310/0286; G09G 2310/08; G09G 2330/021; G11C 19/287

(57) ABSTRACT

A scan circuit is provided. The scan circuit includes a plurality of scan units cascaded. A respective scan unit of the plurality of scan units includes a first subcircuit connected to a first node; a second subcircuit connected to the first node and a second node; a third subcircuit connected to the second node and a third node; a fourth subcircuit connected to a fourth node and a sixth node; and a fifth subcircuit configured to output an output signal through an output terminal, and is connected to the fourth node. The first subcircuit includes an input transistor, a thirteenth transistor, and a fourteenth transistor. A gate electrode of the thirteenth transistor is configured to receive a third clock signal from a third clock terminal. A first electrode of the thirteenth transistor is configured to receive an input signal from an input terminal.

### CROSS-REFERENCE TO RELATED APPLICATION

This application is a continuation of International Application No. PCT/CN2024/131921, filed Nov. 14, 2024, the contents of which are incorporated by reference in the entirety.

### TECHNICAL FIELD

The present invention relates to display technology, more particularly, to a scan circuit, a display apparatus, and a method of operating a scan circuit.

### BACKGROUND

Organic Light Emitting Diode (OLED) display is one of the hotspots in the field of flat panel display research today. Unlike Thin Film Transistor-Liquid Crystal Display (TFT-LCD), which uses a stable voltage to control brightness, OLED is driven by a driving current required to be kept constant to control illumination. The OLED display panel includes a plurality of pixel units configured with pixel-driving circuits arranged in multiple rows and columns. Each pixel-driving circuit includes a driving transistor having a gate terminal connected to one gate line per row and a drain terminal connected to one data line per column. When the row in which the pixel unit is gated is turned on, the switching transistor connected to the driving transistor is turned on, and the data voltage is applied from the data line to the driving transistor via the switching transistor, so that the driving transistor outputs a current corresponding to the data voltage to an OLED device. The OLED device is driven to emit light of a corresponding brightness.

### SUMMARY

In one aspect, the present disclosure provides a scan circuit, comprising a plurality of scan units cascaded; wherein a respective scan unit of the plurality of scan units comprises a first subcircuit connected to a first node; a second subcircuit connected to the first node and a second node; a third subcircuit connected to the second node and a third node; a fourth subcircuit connected to a fourth node and a sixth node; and a fifth subcircuit configured to output an output signal through an output terminal, and is connected to the fourth node; wherein the first subcircuit comprises an input transistor, a thirteenth transistor, and a fourteenth transistor; wherein a gate electrode of the thirteenth transistor is configured to receive a third clock signal from a third clock terminal; a first electrode of the thirteenth transistor is configured to receive an input signal from an input terminal; a second electrode of the thirteenth transistor is connected to a first electrode of the input transistor; a gate electrode of the input transistor is configured to receive a second clock signal from a second clock terminal; a first electrode of the input transistor is connected to the second electrode of the thirteenth transistor; a second electrode of the input transistor is connected to the first node; a gate electrode of the fourteenth transistor is configured to receive an enabling control signal; a first electrode of the fourteenth transistor is configured to receive a second reference voltage signal from a second reference voltage terminal; and a second electrode of the fourteenth transistor is connected to the first node.

Optionally, the first subcircuit further comprises a fifteenth transistor; wherein a gate electrode of the fifteenth transistor is configured to receive a fourth reference voltage signal from a fourth reference voltage terminal; a first electrode of the fifteenth transistor is connected to the first node; and a second electrode of the fifteenth transistor is connected to the sixth node.

Optionally, the first subcircuit further comprises a second input transistor and an eighteenth transistor; wherein a gate electrode of the eighteenth transistor is configured to receive a third clock signal from a third clock terminal, a first electrode of the eighteenth transistor is configured to receive an input signal from an input terminal, a second electrode of the eighteenth transistor is connected to a first electrode of the second input transistor; and a gate electrode of the second input transistor is configured to receive a second clock signal from a second clock terminal, a first electrode of the second input transistor is connected to a second electrode of the eighteenth transistor, a second electrode of the second input transistor is connected to a sixth node.

Optionally, the second subcircuit comprises a first transistor, a fourth transistor, a seventh transistor, and a first capacitor; wherein a gate electrode of the first transistor is connected to the first node, a first electrode of the first transistor is configured to receive the second clock signal from the second clock terminal, a second electrode of the first transistor is connected to a second node; a gate electrode of the fourth transistor is connected to the first node, a first electrode of the fourth transistor is configured to receive a first clock signal from a first clock terminal, a second electrode of the fourth transistor is connected to a fifth node; a gate electrode of the seventh transistor is connected to the second node, a first electrode of the seventh transistor is configured to receive the second reference voltage signal from the second reference voltage terminal, a second electrode of the seventh transistor is connected to the fifth node; and a first electrode of the first capacitor is connected to the first node, a second electrode of the first capacitor is connected to the fifth node.

Optionally, the third subcircuit comprises a sixth transistor, a ninth transistor, a tenth transistor, and a second capacitor; wherein a gate electrode of the sixth transistor is configured to receive the third clock signal from the third clock terminal, a first electrode of the sixth transistor is configured to receive a third reference voltage signal from a third reference voltage terminal, a second electrode of the sixth transistor is connected to the second node; a gate electrode of the ninth transistor is connected to the second node, a first electrode of the ninth transistor is configured to receive the first clock signal from the first clock terminal, a second electrode of the ninth transistor is connected to a third node; a gate electrode of the tenth transistor is configured to receive the first clock signal from the first clock terminal, a first electrode of the tenth transistor is connected to the third node, a second electrode of the tenth transistor is connected to a fourth node; and a first electrode of the second capacitor is connected to the second node, a second electrode of the second capacitor is connected to the third node.

Optionally, the third subcircuit comprises a sixth transistor, a ninth transistor, a tenth transistor, a sixteenth transistor, and a second capacitor; wherein a gate electrode of the sixth transistor is configured to receive the third clock signal from the third clock terminal, a first electrode of the sixth transistor is configured to receive a third reference voltage signal from a third reference voltage terminal, a second electrode of the sixth transistor is connected to a first electrode of the sixteenth transistor; a gate electrode of the sixteenth transistor is configured to receive the fourth reference voltage signal from the fourth reference voltage terminal, a first electrode of the sixteenth transistor is connected to the second electrode of the sixth transistor, a second electrode of the sixteenth transistor is connected to the second node; a gate electrode of the ninth transistor is connected to the second node, a first electrode of the ninth transistor is configured to receive the first clock signal from the first clock terminal, a second electrode of the ninth transistor is connected to a third node; a gate electrode of the tenth transistor is configured to receive the first clock signal from the first clock terminal, a first electrode of the tenth transistor is connected to the third node, a second electrode of the tenth transistor is connected to a fourth node; and a first electrode of the second capacitor is connected to the second node, a second electrode of the second capacitor is connected to the third node.

Optionally, the third subcircuit comprises a sixth transistor, a ninth transistor, a tenth transistor, a sixteenth transistor, and a second capacitor; wherein a gate electrode of the sixth transistor is configured to receive the third clock signal from the third clock terminal, a first electrode of the sixth transistor is configured to receive a third reference voltage signal from a third reference voltage terminal, a second electrode of the sixth transistor is connected to a first electrode of the sixteenth transistor; a gate electrode of the sixteenth transistor is configured to receive the second clock signal from the second clock terminal, a first electrode of the sixteenth transistor is connected to the second electrode of the sixth transistor, a second electrode of the sixteenth transistor is connected to the second node; a gate electrode of the ninth transistor is connected to the second node, a first electrode of the ninth transistor is configured to receive the first clock signal from the first clock terminal, a second electrode of the ninth transistor is connected to a third node; a gate electrode of the tenth transistor is configured to receive the first clock signal from the first clock terminal, a first electrode of the tenth transistor is connected to the third node, a second electrode of the tenth transistor is connected to a fourth node; and a first electrode of the second capacitor is connected to the second node, a second electrode of the second capacitor is connected to the third node.

Optionally, the fourth subcircuit comprises a fifth transistor, an eighth transistor, and a fourth capacitor; wherein a gate electrode of the fifth transistor is connected to a sixth node, a first electrode of the fifth transistor is configured to receive the third reference voltage signal from the third reference voltage terminal, a second electrode of the fifth transistor is connected to an output terminal; a gate electrode of the eighth transistor is connected to a sixth node, a first electrode of the eighth transistor is configured to receive the third clock signal from the third clock terminal, a second electrode of the eighth transistor is connected to the fourth node; and a first electrode of the fourth capacitor is configured to receive the third reference voltage signal from the third reference voltage terminal, a second electrode of the fourth capacitor is connected to the sixth node.

Optionally, the fourth subcircuit comprises a fifth transistor, an eighth transistor, an eleventh transistor, a seventeenth transistor, and a fourth capacitor; wherein a gate electrode of the fifth transistor is connected to a sixth node, a first electrode of the fifth transistor is configured to receive the third reference voltage signal from the third reference voltage terminal, a second electrode of the fifth transistor is connected to an output terminal; a gate electrode of the eighth transistor is connected to a sixth node, a first electrode of the eighth transistor is configured to receive the third clock signal from the third clock terminal, a second electrode of the eighth transistor is connected to the fourth node; a first electrode of the fourth capacitor is configured to receive the third reference voltage signal from the third reference voltage terminal, a second electrode of the fourth capacitor is connected to the sixth node; a gate electrode of the eleventh transistor is configured to receive an enabling control signal, a first electrode of the eleventh transistor is configured to receive a first reference voltage signal from a first reference voltage terminal, a second electrode of the eleventh transistor is connected to the sixth node; and a gate electrode and a first electrode of the seventeenth transistor are connected to the first node, a second electrode of the seventeenth transistor is connected to the sixth node.

Optionally, the fifth subcircuit comprises an output transistor and a third capacitor; wherein a gate electrode of the output transistor is connected to the fourth node, a first electrode of the output transistor is configured to receive the first reference voltage signal from the first reference voltage terminal, a second electrode of the output transistor is connected to the output terminal; and a first electrode of the third capacitor is connected to the fourth node, a second electrode of the third capacitor is configured to receive the first reference voltage signal from the first reference voltage terminal.

Optionally, an orthographic projection of the third clock terminal on a base substrate spaces apart an orthographic projection the output transistor and the fifth transistor on the base substrate from an orthographic projection of capacitors and transistors other than the output transistor and the fifth transistor on the base substrate; and the orthographic projection of capacitors and transistors other than the output transistor and the fifth transistor on the base substrate is between the orthographic projection of the third clock terminal on the base substrate and an orthographic projection of the second clock terminal on the base substrate.

Optionally, a gate electrode of a sixth transistor in the third subcircuit is connected to the second clock terminal; and gate electrodes of the sixth transistor and the input transistor are parts of a unitary structure.

Optionally, a gate electrode of a sixth transistor in the third subcircuit is connected to the third clock terminal; gate electrodes of the sixth transistor and the thirteenth transistor are connected to each other through a gate connecting line; and an orthographic projection of the gate connecting line on the base substrate at least partially overlaps with an orthographic projection of at least one of a first reference voltage terminal or a fourth reference voltage terminal on the base substrate.

Optionally, the respective scan unit comprises a first gate pad comprising a gate electrode of the thirteenth transistor, a second gate pad comprising a gate electrode of a fifth transistor in the fourth subcircuit, and a clock connecting line connecting the first gate pad to the third clock terminal and to a first electrode of an eighth transistor in the fourth subcircuit; and an orthographic projection of the clock connecting line on the base substrate partially overlaps with an orthographic projection of the second gate pad on the base substrate.

Optionally, the respective scan unit comprises a first gate pad comprising a gate electrode of the thirteenth transistor, a second gate pad comprising a gate electrode of a fifth transistor in the fourth subcircuit, and a clock connecting line connecting the first gate pad to a first electrode of an eighth transistor in the fourth subcircuit; a shortest distance between the thirteenth transistor and a fifth transistor in the fourth subcircuit is greater than a shortest distance between the thirteenth transistor and an output transistor in the fifth subcircuit; and an orthographic projection of the clock connecting line on the base substrate is non-overlapping with an orthographic projection of the second gate pad on the base substrate.

Optionally, the respective scan unit comprises a first gate pad comprising a gate electrode of the thirteenth transistor, a second gate pad comprising a gate electrode of a fifth transistor in the fourth subcircuit, a first clock connecting line connecting a first electrode of an eighth transistor in the fourth subcircuit to the third clock terminal, and a second clock connecting line connecting the first gate pad to the third clock terminal; an orthographic projection of the first clock connecting line on the base substrate is non-overlapping with an orthographic projection of the second gate pad on the base substrate; an orthographic projection of the second clock connecting line on the base substrate is non-overlapping with the orthographic projection of the second gate pad on the base substrate; and the orthographic projection of the second gate pad on the base substrate spaces apart the orthographic projection of the first clock connecting line on the base substrate from the orthographic projection of the second clock connecting line on the base substrate.

Optionally, the third clock terminal extends along a first direction; the third clock terminal, the second clock terminal, and the first clock terminal are arranged along a second direction; and an orthographic projection, along the second direction, of an active layer of a fifth transistor in the fourth subcircuit on a plane perpendicular to a semiconductor material layer, a first gate metal layer, a second gate metal layer, a first signal line layer, a second signal line layer, and a third signal line layer covers an orthographic projection, along the second direction, of an active layer of the thirteenth transistor on the plane perpendicular to the semiconductor material layer, the first gate metal layer, the second gate metal layer, the first signal line layer, the second signal line layer, and the third signal line layer.

Optionally, the scan circuit comprises a first adjacent scan unit and a second adjacent scan unit connected to each other; wherein the scan circuit further comprises a fourth clock terminal; a first electrode of an output transistor in the fifth subcircuit and a gate electrode of the thirteenth transistor in the first adjacent scan unit are connected to the third clock terminal through a first via; a first electrode of an output transistor in the fifth subcircuit and a gate electrode of the thirteenth transistor in the second adjacent scan unit are connected to the fourth clock terminal through a second via; an orthographic projection of the first via on a base substrate at least partially overlaps with an orthographic projection of a third capacitor in the first adjacent scan unit on the base substrate; and an orthographic projection of the second via on the base substrate is non-overlapping with an orthographic projection of a third capacitor in the second adjacent scan unit on the base substrate; and the third clock terminal comprise a second electrode of the third capacitor in the first adjacent scan unit, and a second electrode of the third capacitor in the second adjacent scan unit.

In another aspect, the present disclosure provides a display apparatus, comprising the scan circuit described herein, and a display panel connected to the scan circuit.

In another aspect, the present disclosure provides a method of operating a scan circuit; wherein the scan circuit includes a plurality of scan units cascaded; wherein a respective scan unit of the plurality of scan units includes a first subcircuit connected to a first node; a second subcircuit connected to the first node and a second node; a third subcircuit connected to the second node and a third node; a fourth subcircuit connected to a fourth node and a sixth node; and a fifth subcircuit connected to the fourth node; wherein the first subcircuit includes an input transistor, a thirteenth transistor, and a fourteenth transistor; wherein the method comprises providing a third clock signal from a third clock terminal to a gate electrode of the thirteenth transistor; providing an input signal from an input terminal to a first electrode of the thirteenth transistor; connecting a second electrode of the thirteenth transistor to a first electrode of the input transistor; connecting a first electrode of the input transistor to the second electrode of the thirteenth transistor; connecting a second electrode of the input transistor to the first node; connecting a second electrode of the fourteenth transistor to the first node; providing a second clock signal from a second clock terminal to a gate electrode of the input transistor; providing an enabling control signal to a gate electrode of the fourteenth transistor; providing a second reference voltage signal from a second reference voltage terminal to a first electrode of the fourteenth transistor; and outputting output signal through an output terminal in the fifth subcircuit.

### BRIEF DESCRIPTION OF THE FIGURES

The following drawings are merely examples for illustrative purposes according to various disclosed embodiments and are not intended to limit the scope of the present invention.

FIG. 1 is a plan view of an array substrate in some embodiments according to the present disclosure.

FIG. 2A is a circuit diagram illustrating the structure of a pixel driving circuit in some embodiments according to the present disclosure.

FIG. 2B is a timing diagram illustrating the operation of a pixel driving circuit in some embodiments according to the present disclosure.

FIG. 3 is a circuit diagram of a respective scan unit in some embodiments according to the present disclosure.

FIG. 4 is a circuit diagram of a respective scan unit in some embodiments according to the present disclosure.

FIG. 5 is a timing diagram illustrating the operation of a respective scan unit in some embodiments according to the present disclosure.

FIG. 6 is a circuit diagram of a respective scan unit in some embodiments according to the present disclosure.

FIG. 7 is a circuit diagram of a respective scan unit in some embodiments according to the present disclosure.

FIG. 8 is a circuit diagram of a respective scan unit in some embodiments according to the present disclosure.

FIG. 9 is a circuit diagram of a respective scan unit in some embodiments according to the present disclosure.

FIG. 10 is a circuit diagram of a respective scan unit in some embodiments according to the present disclosure.

FIG. 11A is a schematic diagram of a scan circuit in some embodiments according to the present disclosure.

FIG. 11B is a schematic diagram of a scan circuit in some embodiments according to the present disclosure.

FIG. 12 is a timing diagram illustrating the operation of a respective scan unit in some embodiments according to the present disclosure.

FIG. 13A is a schematic diagram illustrating the structure of various layers of a respective scan unit in some embodiments according to the present disclosure.

FIG. 13B is a circuit diagram of a respective scan unit in some embodiments according to the present disclosure.

FIG. 14 is a schematic diagram illustrating the structure of various layers of a respective scan unit in some embodiments according to the present disclosure.

FIG. 15 is a schematic diagram illustrating the structure of various layers of a respective scan unit in some embodiments according to the present disclosure.

FIG. 16 is a schematic diagram illustrating the structure of various layers of a respective scan unit in some embodiments according to the present disclosure.

FIG. 17 is a schematic diagram illustrating the structure of various layers of a respective scan unit in some embodiments according to the present disclosure.

FIG. 18 is a schematic diagram illustrating the structure of various layers of a respective scan unit in some embodiments according to the present disclosure.

FIG. 19 is a schematic diagram illustrating the structure of various layers of a respective scan unit in some embodiments according to the present disclosure.

### DETAILED DESCRIPTION

The disclosure will now be described more specifically with reference to the following embodiments. It is to be noted that the following descriptions of some embodiments are presented herein for purpose of illustration and description only. It is not intended to be exhaustive or to be limited to the precise form disclosed.

The present disclosure provides, inter alia, a scan circuit, a display apparatus, and a method of operating a scan circuit that substantially obviate one or more of the problems due to limitations and disadvantages of the related art. In one aspect, the present disclosure provides a scan circuit. In some embodiments, the scan circuit includes a plurality of scan units cascaded. Optionally, a respective scan unit of the plurality of scan units comprises a first subcircuit connected to a first node; a second subcircuit connected to the first node and a second node; a third subcircuit connected to the second node and a third node; a fourth subcircuit connected to a fourth node and a sixth node; and a fifth subcircuit configured to output an output signal through an output terminal, and is connected to the fourth node. Optionally, the first subcircuit comprises an input transistor and a thirteenth transistor. Optionally, a gate electrode of the thirteenth transistor is configured to receive a third clock signal from a third clock terminal. Optionally, a first electrode of the thirteenth transistor is configured to receive an input signal from an input terminal. Optionally, a second electrode of the thirteenth transistor is connected to a first electrode of the input transistor. Optionally, a gate electrode of the input transistor is configured to receive a second clock signal from a second clock terminal. Optionally, a first electrode of the input transistor is connected to the second electrode of the thirteenth transistor. Optionally, a second electrode of the input transistor is connected to the first node.

Various appropriate pixel driving circuits may be used in the present array substrate. Examples of appropriate driving circuits include 3T1C, 2T1C, 4T1C, 4T2C, 5T2C, 6T1C, 7T1C, 7T2C, 8T1C, and 8T2C. In some embodiments, the respective one of the plurality of pixel driving circuits is an 8T1C driving circuit. Various appropriate light emitting elements may be used in the present array substrate. Examples of appropriate light emitting elements include organic light emitting diodes, quantum dots light emitting diodes, and micro light emitting diodes. Optionally, the light emitting element is micro light emitting diode. Optionally, the light emitting element is an organic light emitting diode including an organic light emitting layer.

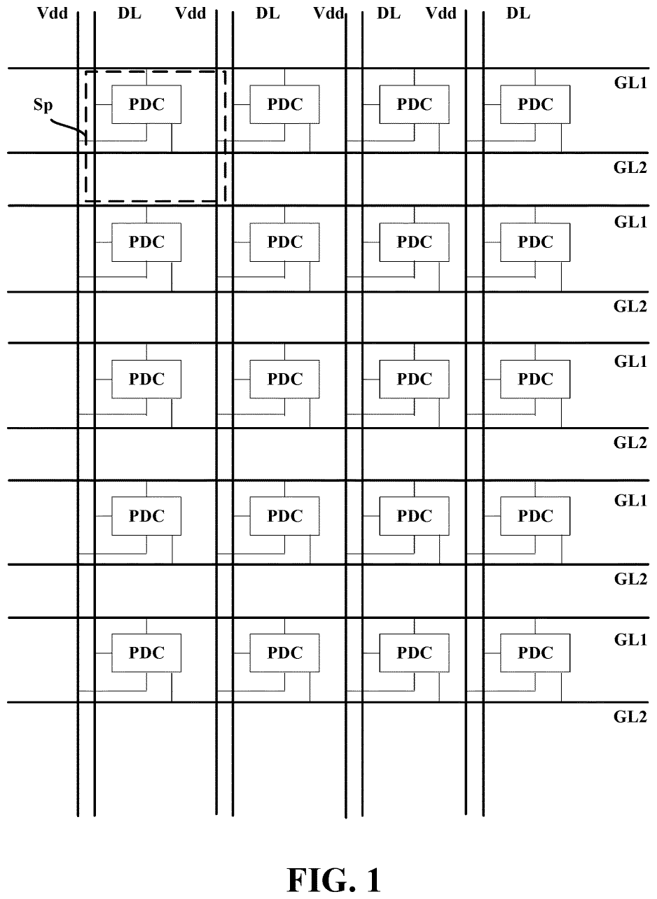

FIG. 1 is a plan view of an array substrate in some embodiments according to the present disclosure. Referring to FIG. 1, the array substrate includes an array of subpixels Sp. Each subpixel includes an electronic component, e.g., a light emitting element. In one example, the light emitting element is driven by a respective pixel driving circuit PDC. The array substrate includes a plurality of first gate lines GL1, a plurality of second gate lines GL2, a plurality of data lines DL, a plurality of first voltage supply line (e.g., a respective first voltage supply line Vdd), and a plurality of second voltage supply line (e.g., a respective second voltage supply line Vss). Light emission in a respective subpixel Sp is driven by a respective pixel driving circuit PDC. In one example, a high voltage signal (e.g., a VDD signal) is input, through the respective high voltage supply line Vdd, to the respective pixel driving circuit PDC connected to an anode of the light emitting element; a low voltage signal (e.g., a VSS signal) is input, through a low voltage supply line, to a cathode of the light emitting element. A voltage difference between the high voltage signal (e.g., the VDD signal) and the low voltage signal (e.g., the VSS signal) is a driving voltage ΔV that drives light emission in the light emitting element.

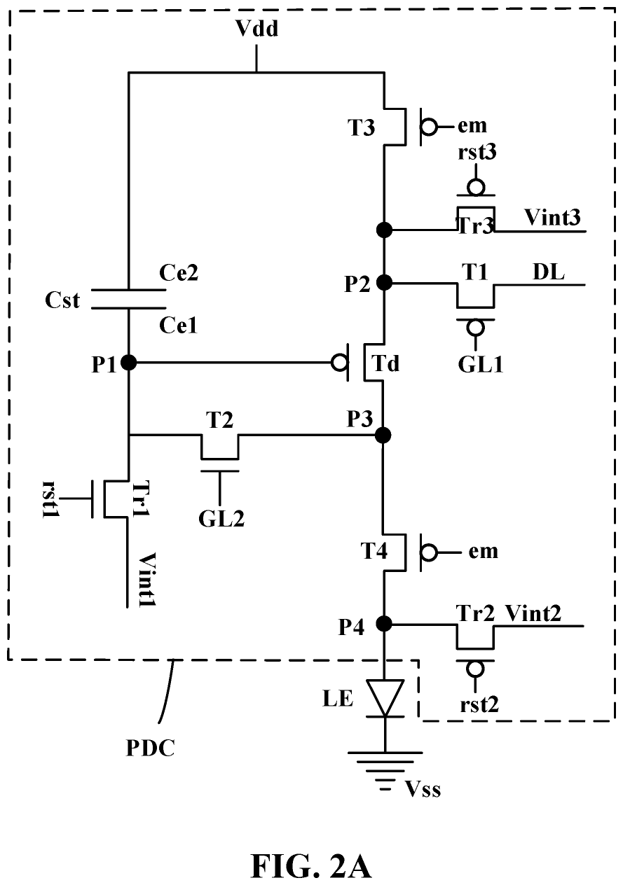

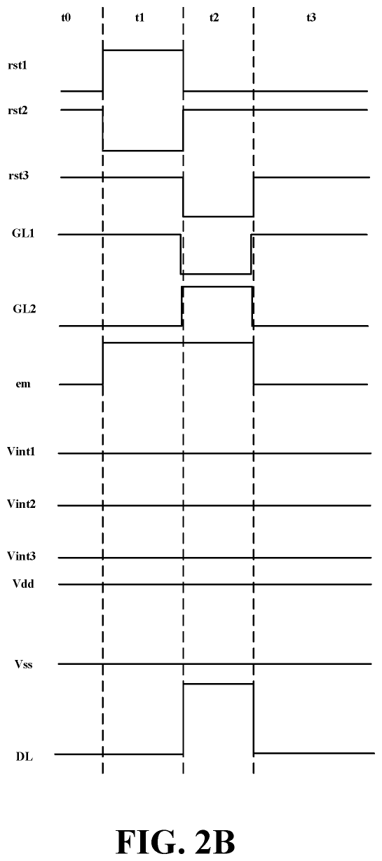

FIG. 2A is a circuit diagram illustrating the structure of a pixel driving circuit in some embodiments according to the present disclosure. Referring to FIG. 2A, in some embodiments, the pixel driving circuit includes a driving transistor Td; a storage capacitor Cst having a first capacitor electrode Ce1 and a second capacitor electrode Ce2; a first reset transistor Tr1 having a gate electrode connected to a respective first reset control signal line rst1 of a plurality of first reset control signal lines, a first electrode connected to a respective first reset signal line Vint1 of a plurality of first reset signal lines, and a second electrode connected to a first capacitor electrode Ce1 of the storage capacitor Cst and a gate electrode of the driving transistor Td; a second reset transistor Tr2 having a gate electrode connected to a respective second reset control signal line rst2 of a plurality of second reset control signal lines, a first electrode connected to a respective second reset signal line Vint2 of a plurality of second reset signal lines, and a second electrode connected to a second electrode of the fourth transistor T4 and an anode of the light emitting element LE; a third reset transistor Tr3 having a gate electrode connected to a respective third reset control signal line rst3 of a plurality of third reset control signal lines, a first electrode connected to a respective third reset signal line Vint3 of a plurality of third reset signal lines, and a second electrode connected to the first electrode of the driving transistor Td; a first transistor T1 (e.g., a data write transistor) having a gate electrode connected to a respective first gate line GL1 of a plurality of first gate lines, a first electrode connected to a respective data line DL of a plurality of data lines, and a second electrode connected to a first electrode of the driving transistor Td; a second transistor T2 (e.g., a compensating transistor) having a gate electrode connected to a respective second gate line GL2 of a plurality of second gate lines, a first electrode connected to the first capacitor electrode Ce1 of the storage capacitor Cst and the gate electrode of the driving transistor Td, and a second electrode connected to the second electrode of the driving transistor Td; a third transistor T3 having a gate electrode connected to a respective light emitting control signal line em of a plurality of light emitting control signal lines, a first electrode connected to a respective first voltage supply line Vdd of a plurality of first voltage supply lines, and a second electrode connected to the first electrode of the driving transistor Td and the second electrode of the first transistor T1; and a fourth transistor T4 having a gate electrode connected to the respective light emitting control signal line em of the plurality of light emitting control signal lines, a first electrode connected to second electrodes of the driving transistor Td and the second transistor T2, and a second electrode connected to an anode of a light emitting element LE and the second electrode of the second reset transistor Tr2. The second capacitor electrode Ce2 is connected to the respective voltage supply line and the first electrode of the third transistor T3.

In some embodiments, the pixel driving circuit includes a driving transistor Td, a data write transistor (e.g., the first transistor T1), a compensating transistor (e.g., the second transistor T2), two light emitting control transistors (e.g., the third transistor T3 and the fourth transistor T4), and three reset transistors (e.g., the first reset transistor Tr1, the second reset transistor Tr2, and the third reset transistor Tr3).

As used herein, a first electrode or a second electrode refers to one of a first terminal and a second terminal of a transistor, the first terminal and the second terminal being connected to an active layer of the transistor. A direction of a current flowing through the transistor may be configured to be from a first electrode to a second electrode, or from a second electrode to a first electrode. Accordingly, depending on the direction of the current flowing through the transistor, in one example, the first electrode is configured to receive an input signal and the second electrode is configured to output an output signal; in another example, the second electrode is configured to receive an input signal and the first electrode is configured to output an output signal.

The pixel driving circuit further include a node P1, a node P2, a node P3, and a node P4. The node P1 is connected to the gate electrode of the driving transistor Td, the first capacitor electrode Ce1, the first electrode of the second transistor T2, and the second electrode of the first reset transistor Tr1. The node P2 is connected to the second electrode of the third transistor T3, the second electrode of the first transistor T1, the second electrode of the third reset transistor Tr3, and the first electrode of the driving transistor Td. The node P3 is connected to the second electrode of the driving transistor Td, the second electrode of the second transistor T2, and the first electrode of the fourth transistor T4. The node P4 is connected to the second electrode of the fourth transistor T4, the second electrode of the second reset transistor Tr2, and the anode of the light emitting element LE.

The array substrate in some embodiments includes a plurality of subpixels. In some embodiments, the plurality of subpixels include a respective first subpixel, a respective second subpixel, and a respective third subpixel. Optionally, a respective pixel of the array substrate includes the respective first subpixel, the respective second subpixel, and the respective third subpixel. The plurality of subpixels in the array substrate are arranged in an array. In one example, the array of the plurality of subpixels includes a S1-S2-S3 format repeating array, in which S1 stands for the respective first subpixel, S2 stands for the respective second subpixel, and S3 stands for the respective third subpixel. In another example, the S1-S2-S3 format is a C1-C2-C3 format, in which C1 stands for the respective first subpixel of a first color, C2 stands for the respective second subpixel of a second color, and C3 stands for the respective third subpixel of a third color. In another example, the C1-C2-C3 format is an R-G-B format, in which the respective first subpixel is a red subpixel, the respective second subpixel is a green subpixel, and the respective third subpixel is a blue subpixel.

In another example, the array of the plurality of subpixels includes a S1-S2-S3-S4 format repeating array, in which S1 stands for the respective first subpixel, S2 stands for the respective second subpixel, S3 stands for the respective third subpixel, and S4 stands for the respective fourth subpixel. In another example, the S1-S2-S3-S4 format is a C1-C2-C3-C4 format, in which C1 stands for the respective first subpixel of a first color, C2 stands for the respective second subpixel of a second color, C3 stands for the respective third subpixel of a third color, and C4 stands for the respective fourth subpixel of a fourth color. In another example, the S1-S2-S3-S4 format is a C1-C2-C3-C2′ format, in which C1 stands for the respective first subpixel of a first color, C2 stands for the respective second subpixel of a second color, C3 stands for the respective third subpixel of a third color, and C2′ stands for the respective fourth subpixel of the second color. In another example, the C1-C2-C3-C2′ format is a R-G-B-G format, in which the respective first subpixel is a red subpixel, the respective second subpixel is a green subpixel, the respective third subpixel is a blue subpixel, and the respective fourth subpixel is a green subpixel.

In some embodiments, a minimum repeating unit of the plurality of subpixels of the array substrate includes a respective first subpixel, a respective second subpixel, and a respective third subpixel. Optionally, each of the respective first subpixel, the respective second subpixel, and the respective third subpixel, includes the first transistor T1, the second transistor T2, the third transistor T3, the fourth transistor T4, the driving transistor Td, the first reset transistor Tr1, the second reset transistor Tr2, the third reset transistor Tr3, and the storage capacitor Cst.

In alternative embodiments, a minimum repeating unit of the plurality of subpixels of the array substrate includes a respective first subpixel, a respective second subpixel, a respective third subpixel, and a respective fourth subpixel. Optionally, each of the respective first subpixel, the respective second subpixel, the respective third subpixel, and the respective fourth subpixel includes the first transistor T1, the second transistor T2, the third transistor T3, the fourth transistor T4, the driving transistor Td, the first reset transistor Tr1, the second reset transistor Tr2, the third reset transistor Tr3, and the storage capacitor Cst.

The present disclosure may be implemented in pixel driving circuit having transistors of various types, including a pixel driving circuit having p-type transistors, a pixel driving circuit having n-type transistors, and a pixel driving circuit having one or more p-type transistors and one or more n-type transistors. Referring to FIG. 2A, the second transistor T2 and the first reset transistor Tr1 are n-type transistors such as metal oxide transistors, and other transistors are p-type transistors such as polysilicon transistors. For a p-type transistor, an effective control signal (e.g., a turn-on control signal) is a low voltage signal, and an ineffective control signal (e.g., a turn-off control signal) is a high voltage signal. For an n-type transistor, an effective control signal (e.g., a turn-on control signal) is a high voltage signal, and an ineffective control signal (e.g., a turn-off control signal) is a low voltage signal.

FIG. 2B is a timing diagram illustrating the operation of a pixel driving circuit in some embodiments according to the present disclosure. Referring to FIG. 2A and FIG. 2B, during one frame of image, the operation of the pixel driving circuit includes a reset sub-phase t1, a data write sub-phase t2, and a light emitting sub-phase t3. In the initial sub-phase t0, a turning-off reset control signal is provided through the respective first reset control signal line rst1 to the gate electrode of the first reset transistor Tr1 to turn off the first reset transistor Tr1. A turning-off reset control signal is provided through the respective second reset control signal line rst2 to the gate electrode of the second reset transistor Tr2 to turn off the second reset transistor Tr2. A turning-off reset control signal is provided through the respective third reset control signal line rst3 to the gate electrode of the third reset transistor Tr3 to turn off the third reset transistor Tr3. In the initial sub-phase to, the respective first gate line GL1 and the respective second gate line GL2 are provided with a turning-off signal, thus the first transistor T1 and the second transistor T2 are turned off.

In the reset sub-phase t1, a turning-on reset control signal is provided through the first reset control signal line rst1 to the gate electrode of the first reset transistor Tr1 to turn on the first reset transistor Tr1; allowing an initialization voltage signal from the respective first reset signal line Vint1 to pass from a first electrode of the first reset transistor Tr1 to a second electrode of the first reset transistor Tr1, and in turn to the first capacitor electrode Ce1 and the gate electrode of the driving transistor Td. The gate electrode of the driving transistor Td is initialized. In the reset sub-phase t1, a turning-on reset control signal is provided through the respective second reset control signal line rst2 to the gate electrode of the second reset transistor Tr2 to turn on the second reset transistor Tr2; allowing an initialization voltage signal from the respective second reset signal line Vint2 to pass from a first electrode of the second reset transistor Tr2 to a second electrode of the second reset transistor Tr2; and in turn to the node P4. The anode of the light emitting element LE is initialized. The second capacitor electrode Ce2 receives a high voltage signal from the respective first voltage supply line Vdd. The first capacitor electrode Ce1 is charged in the reset sub-phase t1 due to an increasing voltage difference between the first capacitor electrode Ce1 and the second capacitor electrode Ce2. In the reset sub-phase t1, the respective first gate line GL1 and the respective second gate line GL2 are provided with a turning-off signal, thus the first transistor T1 and the second transistor T2 are turned off. The respective light emitting control signal line em is provided with a high voltage signal to turn off the third transistor T3 and the fourth transistor T4.

In the data write sub-phase t2, the turning-off reset control signal is again provided through the respective first reset control signal line rst1 to the gate electrode of the first reset transistor Tr1 to turn off the first reset transistor Tr1. The respective first gate line GL1 and the respective second gate line GL2 are provided with turning-on signals, thus the first transistor T1 and the second transistor T2 are turned on. A second electrode of the driving transistor Td is connected with the second electrode of the second transistor T2. A gate electrode of the driving transistor Td is electrically connected with the first electrode of the second transistor T2. Because the second transistor T2 is turned on in the data write sub-phase t2, the gate electrode and the second electrode of the driving transistor Td are connected and short circuited, and only the PN junction between the gate electrode and a first electrode of the driving transistor Td is effective, thus rendering the driving transistor Td in a diode connecting mode. The first transistor T1 is turned on in the data write sub-phase t2. The data voltage signal transmitted through the respective data line DL is received by a first electrode of the first transistor T1, and in turn transmitted to the first electrode of the driving transistor Td, which is connected to the second electrode of the first transistor T1. A node P2 connecting to the first electrode of the driving transistor Td has a voltage level of the data voltage signal. Because only the PN junction between the gate electrode and a first electrode of the driving transistor Td is effective, the voltage level at the node P1 in the data write sub-phase t2 increase gradually to (Vdata+Vth), wherein the Vdata is the voltage level of the data voltage signal, and the Vth is the voltage level of the threshold voltage Th of the PN junction. The storage capacitor Cst is discharged because the voltage difference between the first capacitor electrode Ce1 and the second capacitor electrode Ce2 is reduced to a relatively small value. The respective light emitting control signal line em is provided with a high voltage signal to turn off the third transistor T3 and the fourth transistor T4.

A turning-on reset control signal is provided through the respective third reset control signal line rst3 to the gate electrode of the third reset transistor Tr3 to turn on the third reset transistor Tr3; allowing an initialization voltage signal from the respective third reset signal line Vint3 to pass from a first electrode of the third reset transistor Tr3 to a second electrode of the third reset transistor Tr3; and in turn to the node P2. The node P2 is initialized.

In the light emitting sub-phase t3, the turning-off reset control signal is again provided through the respective first reset control signal line rst1 to the gate electrode of the first reset transistor Tr1 to turn off the first reset transistor Tr1. The respective first gate line GL1 and the respective second gate line GL2 are provided with a turning-off signal, the first transistor T1 and the second transistor T2 are turned off. The respective light emitting control signal line em is provided with a low voltage signal to turn on the third transistor T3 and the fourth transistor T4. The voltage level at the node P1 in the light emitting sub-phase t3 is maintained at (Vdata+Vth), the driving transistor Td is turned on by the voltage level, and working in the saturation area. A path is formed through the third transistor T3, the driving transistor Td, the fourth transistor T4, to the light emitting element LE. The driving transistor Td generates a driving current for driving the light emitting element LE to emit light. A voltage level at a node P3 connected to the second electrode of the driving transistor Td equals to a light emitting voltage of the light emitting element LE.

In one aspect, the present disclosure provides a scan circuit. In some embodiments, the scan circuit comprises a plurality of stages, a respective stage of the plurality of stages comprising a respective scan unit of a plurality of scan units. The scan circuit in some embodiments is configured to provide control signals to rows of subpixels in a display panel. Examples of control signals include gate scanning signals, reset control signals, and light emitting control signals. In one example, the scan circuit is a gate scanning signal scan circuit configured to provide gate scanning signals to the plurality of gate lines. In another example, the scan circuit is a light emitting control signal scan circuit configured to provide light emitting control signals to the plurality of light emitting control signal lines. In another example, the scan circuit is a reset control signal scan circuit configured to provide reset control signals to the plurality of reset control signal lines.

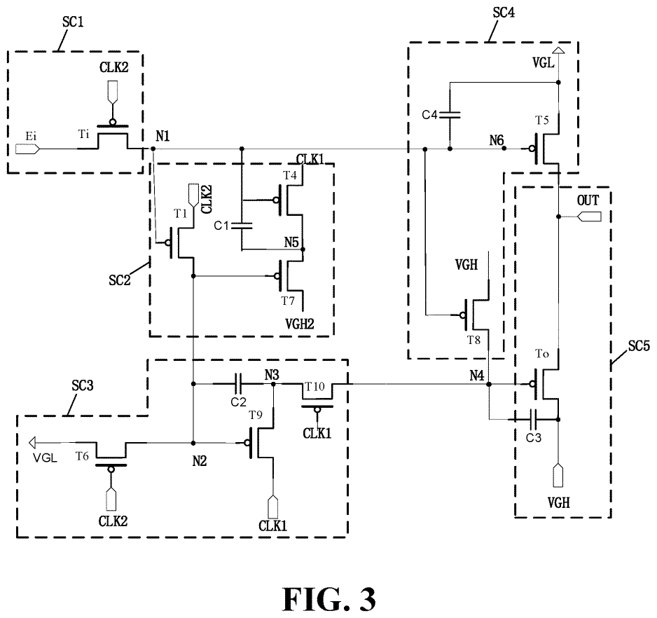

FIG. 3 is a circuit diagram of a respective scan unit in some embodiments according to the present disclosure. Referring to FIG. 3, the respective scan unit in some embodiments includes a first subcircuit SC1, a second subcircuit SC2, a third subcircuit SC3, a fourth subcircuit SC4, and a fifth subcircuit SC5.

In some embodiments, the first subcircuit SC1 is configured to receive an input signal from an input terminal Ei. In some embodiments, the first subcircuit SC1 is connected to a first node N1.

In some embodiments, the second subcircuit SC2 is connected to the first node N1, connected to a second node N2.

In some embodiments, the third subcircuit SC3 is connected to the second node N2, and connected to a third node N3.

In some embodiments, the fourth subcircuit SC4 is connected to a fourth node N4, and connected to a sixth node N6.

In some embodiments, the fifth subcircuit SC5 is configured to output an output signal through an output terminal OUT. In some embodiments, the fifth subcircuit SC5 is connected to the fourth node N4.

In some embodiments, the first subcircuit SC1 includes an input transistor Ti. A gate electrode of the input transistor T1 is configured to receive a second clock signal from a second clock terminal CLK2. A first electrode of the input transistor T1 is configured to receive an input signal from an input terminal Ei. A second electrode of the input transistor T1 is connected to a first node N1.

In some embodiments, the second subcircuit SC2 includes a first transistor T1, a fourth transistor T4, a seventh transistor T7, and a first capacitor C1. A gate electrode of the first transistor T1 is connected to the first node N1. A first electrode of the first transistor T1 is configured to receive the second clock signal from the second clock terminal CLK2. A second electrode of the first transistor T1 is connected to a second node N2.

A gate electrode of the fourth transistor T4 is connected to the first node N1. A first electrode of the fourth transistor T4 is configured to receive a first clock signal from a first clock terminal CLK1. A second electrode of the fourth transistor T4 is connected to a fifth node N5.

A gate electrode of the seventh transistor T7 is connected to the second node N2. A first electrode of the seventh transistor T7 is configured to receive a second reference voltage signal from a second reference voltage terminal VGH2. A second electrode of the seventh transistor T7 is connected to the fifth node N5.

A first electrode of the first capacitor C1 is connected to the first node N1. A second electrode of the first capacitor C1 is connected to the fifth node N5.

In some embodiments, the third subcircuit SC3 includes a sixth transistor T6, a ninth transistor T9, a tenth transistor T10, and a second capacitor C2. A gate electrode of the sixth transistor T6 is configured to receive the second clock signal from the second clock terminal CLK2. A first electrode of the sixth transistor T6 is configured to receive a third reference voltage signal from a third reference voltage terminal VGL. A second electrode of the sixth transistor T6 is connected to the second node N2.

A gate electrode of the ninth transistor T9 is connected to the second node N2. A first electrode of the ninth transistor T9 is configured to receive the first clock signal from the first clock terminal CLK1. A second electrode of the ninth transistor T9 is connected to a third node N3.

A gate electrode of the tenth transistor T10 is configured to receive the first clock signal from the first clock terminal CLK1. A first electrode of the tenth transistor T10 is connected to the third node N3. A second electrode of the tenth transistor T10 is connected to a fourth node N4.

A first electrode of the second capacitor C2 is connected to the second node N2. A second electrode of the second capacitor C2 is connected to the third node N3.

In some embodiments, the fourth subcircuit SC4 includes a fifth transistor T5, an eighth transistor T8, and a fourth capacitor C4. A gate electrode of the fifth transistor T5 is connected to a sixth node N6. A first electrode of the fifth transistor T5 is configured to receive the third reference voltage signal from the third reference voltage terminal VGL. A second electrode of the fifth transistor T5 is connected to an output terminal OUT.

A gate electrode of the eighth transistor T8 is connected to a sixth node N6. A first electrode of the eighth transistor T8 is configured to receive a first reference voltage signal from a first reference voltage terminal VGH. A second electrode of the eighth transistor T8 is connected to the fourth node N4.

In some embodiments, the first reference voltage signal, the second reference voltage signal, and the third reference voltage signal are different from each other. In some embodiments, the first reference voltage signal, the second reference voltage signal, and the third reference voltage signal are constant voltage signals. In some embodiments, the first reference voltage signal has a voltage level higher than a voltage level of the third reference voltage signal. In some embodiments, the second reference voltage signal has a voltage level higher than a voltage level of the third reference voltage signal.

A first electrode of the fourth capacitor C4 is configured to receive the third reference voltage signal from the third reference voltage terminal VGL. A second electrode of the fourth capacitor C4 is connected to the sixth node N6. In the respective scan unit depicted in FIG. 3, the first node N1 and the sixth node N6 are electrically connected without any intervening transistor or capacitor.

In some embodiments, the fifth subcircuit SC5 includes an output transistor To and a third capacitor C3. A gate electrode of the output transistor To is connected to the fourth node N4. A first electrode of the output transistor To is configured to receive the first reference voltage signal from the first reference voltage terminal VGH. A second electrode of the output transistor To is connected to the output terminal OUT.

A first electrode of the third capacitor C3 is connected to the fourth node N4. A second electrode of the third capacitor C3 is configured to receive the first reference voltage signal from the first reference voltage terminal VGH.

The inventors of the present disclosure discover that, when the scan circuit is configured to provide driving signals for an n-type transistor (e.g., T2 in FIG. 2A), it is necessary for the respective scan unit to maintain a low-level signal for an extended period because the n-type transistor requires a high voltage level to turn on. For the respective scan unit to maintain a low-level signal for an extended period, the input transistor (Ti in FIG. 3) is configured to receive a low voltage level signal for the extended period, causing the threshold voltage of the input transistor to shift. The shift can easily lead to the unintentional turning-on of the input transistor, which may mistakenly transmit a low-level signal to the first node N1. As a result, the fifth transistor T5 might be unintentionally turned on, outputting a low voltage level signal from the third reference voltage terminal VGL, which would cause an incorrect output, leading to instability in the scan circuit output.

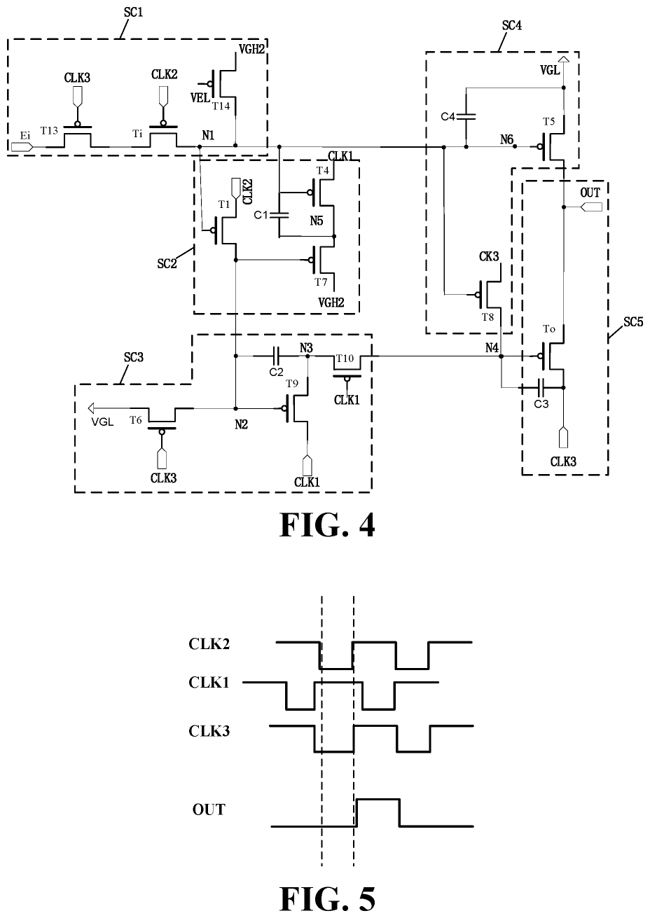

FIG. 4 is a circuit diagram of a respective scan unit in some embodiments according to the present disclosure. Referring to FIG. 4, the respective scan unit in some embodiments includes a first subcircuit SC1, a second subcircuit SC2, a third subcircuit SC3, a fourth subcircuit SC4, and a fifth subcircuit SC5.

In some embodiments, the first subcircuit SC1 is configured to receive an input signal from an input terminal Ei. The input terminal Ei is configured to receive a start signal or an output signal from an output terminal of a previous scan unit (e.g., a (n−1)-th scan unit SU(n−1), a (n−2)-th scan unit, or a (n−3)-th scan unit). As used herein, the term “previous scan unit” is not limited to immediately previous scan unit (e.g., the (n−1)-th scan unit), but includes any appropriate previous scan unit (e.g., the (n−2)-th scan unit, or the (n−3)-th scan unit). In some embodiments, the first subcircuit SC1 is connected to a first node N1.

In some embodiments, the second subcircuit SC2 is connected to the first node N1, connected to a second node N2.

In some embodiments, the third subcircuit SC3 is connected to the second node N2, and connected to a third node N3.

In some embodiments, the fourth subcircuit SC4 is connected to a fourth node N4, and connected to a sixth node N6.

In some embodiments, the fifth subcircuit SC5 is configured to output an output signal through an output terminal OUT. In some embodiments, the fifth subcircuit SC5 is connected to the fourth node N4.

In some embodiments, the first subcircuit SC1 includes an input transistor T1, a thirteenth transistor T13, and a fourteenth transistor T14.

A gate electrode of the thirteenth transistor T13 is configured to receive a third clock signal from a third clock terminal CLK3. A first electrode of the thirteenth transistor T13 is configured to receive an input signal from an input terminal Ei. A second electrode of the thirteenth transistor T13 is connected to a first electrode of the input transistor T1.

A gate electrode of the input transistor T1 is configured to receive a second clock signal from a second clock terminal CLK2. A first electrode of the input transistor T1 is connected to a second electrode of the thirteenth transistor T13. A second electrode of the input transistor T1 is connected to a first node N1.

A gate electrode of the fourteenth transistor T14 is configured to receive an enabling control signal VEL. A first electrode of the fourteenth transistor T14 is configured to receive a second reference voltage signal from a second reference voltage terminal VGH2. A second electrode of the fourteenth transistor T14 is connected to the first node N1.

In some embodiments, the second subcircuit SC2 includes a first transistor T1, a fourth transistor T4, a seventh transistor T7, and a first capacitor C1. A gate electrode of the first transistor T1 is connected to the first node N1. A first electrode of the first transistor T1 is configured to receive the second clock signal from the second clock terminal CLK2. A second electrode of the first transistor T1 is connected to a second node N2.

A gate electrode of the fourth transistor T4 is connected to the first node N1. A first electrode of the fourth transistor T4 is configured to receive a first clock signal from a first clock terminal CLK1. A second electrode of the fourth transistor T4 is connected to a fifth node N5.

A gate electrode of the seventh transistor T7 is connected to the second node N2. A first electrode of the seventh transistor T7 is configured to receive the second reference voltage signal from the second reference voltage terminal VGH2. A second electrode of the seventh transistor T7 is connected to the fifth node N5.

A first electrode of the first capacitor C1 is connected to the first node N1. A second electrode of the first capacitor C1 is connected to the fifth node N5.

In some embodiments, the third subcircuit SC3 includes a sixth transistor T6, a ninth transistor T9, a tenth transistor T10, and a second capacitor C2. A gate electrode of the sixth transistor T6 is configured to receive the third clock signal from the third clock terminal CLK3. A first electrode of the sixth transistor T6 is configured to receive a third reference voltage signal from a third reference voltage terminal VGL. A second electrode of the sixth transistor T6 is connected to the second node N2.

A gate electrode of the ninth transistor T9 is connected to the second node N2. A first electrode of the ninth transistor T9 is configured to receive the first clock signal from the first clock terminal CLK1. A second electrode of the ninth transistor T9 is connected to a third node N3.

A gate electrode of the tenth transistor T10 is configured to receive the first clock signal from the first clock terminal CLK1. A first electrode of the tenth transistor T10 is connected to the third node N3. A second electrode of the tenth transistor T10 is connected to a fourth node N4.

A first electrode of the second capacitor C2 is connected to the second node N2. A second electrode of the second capacitor C2 is connected to the third node N3.

In some embodiments, the fourth subcircuit SC4 includes a fifth transistor T5, an eighth transistor T8, and a fourth capacitor C4. A gate electrode of the fifth transistor T5 is connected to a sixth node N6. A first electrode of the fifth transistor T5 is configured to receive the third reference voltage signal from the third reference voltage terminal VGL. A second electrode of the fifth transistor T5 is connected to an output terminal OUT.

A gate electrode of the eighth transistor T8 is connected to a sixth node N6. A first electrode of the eighth transistor T8 is configured to receive the third clock signal from the third clock terminal CLK3. A second electrode of the eighth transistor T8 is connected to the fourth node N4.

In some embodiments, the first reference voltage signal, the second reference voltage signal, and the third reference voltage signal are different from each other. In some embodiments, the first reference voltage signal, the second reference voltage signal, and the third reference voltage signal are constant voltage signals. In some embodiments, the first reference voltage signal has a voltage level higher than a voltage level of the third reference voltage signal. In some embodiments, the second reference voltage signal has a voltage level higher than a voltage level of the third reference voltage signal.

A first electrode of the fourth capacitor C4 is configured to receive the third reference voltage signal from the third reference voltage terminal VGL. A second electrode of the fourth capacitor C4 is connected to the sixth node N6. In the respective scan unit depicted in FIG. 4, the first node N1 and the sixth node N6 are electrically connected without any intervening transistor or capacitor.

In some embodiments, the fifth subcircuit SC5 includes an output transistor To and a third capacitor C3. A gate electrode of the output transistor To is connected to the fourth node N4. A first electrode of the output transistor To is configured to receive the third clock signal from the third clock terminal (alternatively, the first reference voltage signal from the first reference voltage terminal VGH). A second electrode of the output transistor To is connected to the output terminal OUT.

A first electrode of the third capacitor C3 is connected to the fourth node N4. A second electrode of the third capacitor C3 is configured to receive the third clock signal from the third clock terminal (alternatively, the first reference voltage signal from the first reference voltage terminal VGH).

The inventors of the present disclosure discover that, by having the thirteenth transistor T13 and the fourteenth transistor T14 in the first subcircuit, the effect of low level signal on the input transistor Ti can be mitigated. The thirteenth transistor T13 is placed in front of the input transistor Ti, where the gate electrode of the input transistor T1 is connected to the second clock terminal CLK2, and the gate electrode of the thirteenth transistor T13 is connected to the third clock terminal CLK3. The main function of the thirteenth transistor T13 is to isolate the effect of the low level signal on the input transistor T1.

FIG. 5 is a timing diagram illustrating the operation of a respective scan unit in some embodiments according to the present disclosure. Referring to FIG. 5, in some embodiments, a starting point of an effective voltage signal (e.g., a low level voltage signal) of the second clock signal provided by the second clock terminal CLK2 is slightly later than a starting point of an effective voltage signal (e.g., a low level voltage signal) of the third clock signal provided by the third clock terminal CLK3. By adjusting the starting point of the effective voltage signal of the second clock signal, the normal output of the respective scan unit can be controlled.

Even if the thirteenth transistor T13 experiences threshold voltage shift due to the low level signal, the input transistor Ti further protects against this, reducing the chances of incorrect output from input transistor Ti. Additionally, when normal scan unit output is needed, since the third clock signal activates earlier, it allows the first electrode of the input transistor Ti to be precharged, ensuring that the input transistor Ti can properly control the voltage at the first node N1 of the respective scan unit.

In some embodiments, a starting point of an effective voltage signal (e.g., a low level voltage signal) of the second clock signal provided by the second clock terminal CLK2 is slightly later than a starting point of an effective voltage signal (e.g., a low level voltage signal) of the third clock signal provided by the third clock terminal CLK3. In some embodiments, the starting point of an effective voltage signal (e.g., a low level voltage signal) of the second clock signal provided by the second clock terminal CLK2 is slightly later than the starting point of an effective voltage signal (e.g., a low level voltage signal) of the third clock signal provided by the third clock terminal CLK3 by 0.01 μs to 0.5 μs, e.g., 0.01 μs to 0.05 μs, 0.05 μs to 0.1 μs, 0.1 μs to 0.2 μs, 0.2 μs to 0.3 μs, 0.3 μs to 0.4 μs, or 0.4 μs to 0.5 μs.

In some embodiments, a time point of transitioning from an effective voltage signal (e.g., a low level voltage signal) to an ineffective voltage signal (e.g., a high level voltage signal) of the second clock signal provided by the second clock terminal CLK2 is the same as a time point of transitioning from an effective voltage signal (e.g., a low level voltage signal) to an ineffective voltage signal (e.g., a high level voltage signal) of the third clock signal provided by the third clock terminal CLK3.

In alternative embodiments, a time point of transitioning from an effective voltage signal (e.g., a low level voltage signal) to an ineffective voltage signal (e.g., a high level voltage signal) of the second clock signal provided by the second clock terminal CLK2 is later than a time point of transitioning from an effective voltage signal (e.g., a low level voltage signal) to an ineffective voltage signal (e.g., a high level voltage signal) of the third clock signal provided by the third clock terminal CLK3. Optionally, the time point of transitioning from an effective voltage signal (e.g., a low level voltage signal) to an ineffective voltage signal (e.g., a high level voltage signal) of the second clock signal provided by the second clock terminal CLK2 is later than the time point of transitioning from an effective voltage signal (e.g., a low level voltage signal) to an ineffective voltage signal (e.g., a high level voltage signal) of the third clock signal provided by the third clock terminal CLK3 by 0.01 μs to 0.5 μs, e.g., 0.01 μs to 0.05 μs, 0.05 μs to 0.1 μs, 0.1 μs to 0.2 μs, 0.2 μs to 0.3 μs, 0.3 μs to 0.4 μs, or 0.4 μs to 0.5 μs.

The inventors of the present disclosure discover that, the timing scheme according to the present disclosure can effectively block the voltage transmission from the input terminal Ei to the first node N1. By adjusting the starting point of turning on of the input transistor Ti via the second clock signal, the normal output of the respective scan unit can be ensured.

In some embodiments, a first ratio of channel width to channel length of a channel part of the thirteenth transistor is equal to or less than a second ratio of channel width to channel length of a channel part of the input transistor. In some embodiments, the first ratio is equal to or less than the second ratio, the first ratio is in a range of 1.4 to 2.5 (e.g., 1.4 to 1.5, 1.5 to 1.6, 1.6 to 1.7, 1.7 to 1.8, 1.8 to 1.9, 1.9 to 2.0, 2.0 to 2.1, 2.1 to 2.2, 2.2 to 2.3, 2.3 to 2.4, or 2.4 to 2.5), and the second ratio is in a range of 1.5 to 4.5 (e.g., 1.5 to 1.6, 1.6 to 1.7, 1.7 to 1.8, 1.8 to 1.9, 1.9 to 2.0, 2.0 to 2.1, 2.1 to 2.2, 2.2 to 2.3, 2.3 to 2.4, 2.4 to 2.5, 2.5 to 2.6, 2.6 to 2.7, 2.7 to 2.8, 2.8 to 2.9, 2.9 to 3.0, 3.0 to 3.1, 3.1 to 3.2, 3.2 to 3.3, 3.3 to 3.4, 3.4 to 3.5, 3.5 to 3.6, 3.6 to 3.7, 3.7 to 3.8, 3.8 to 3.9, 3.9 to 4.0, 4.0 to 4.1, 4.1 to 4.2, 4.2 to 4.3, 4.3 to 4.4, or 4.4 to 4.5).

In the respective scan unit depicted in FIG. 5, as compared to the respective scan unit depicted in FIG. 3, the first electrode of the eight transistor T8 (a reset transistor) is configured to receive a third clock signal instead of a first reference voltage signal, the first electrode of the output transistor To is configured to receive a third clock signal instead of a first reference voltage signal. By using the third clock signal, the energy consumption of the respective scan unit can be lowered.

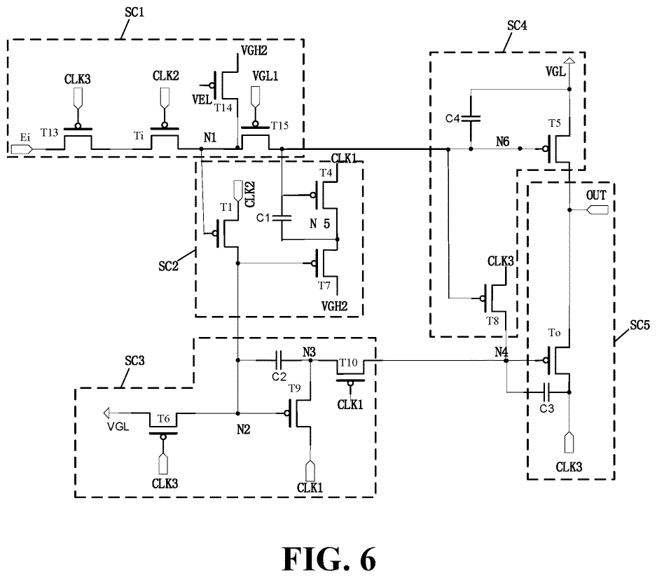

FIG. 6 is a circuit diagram of a respective scan unit in some embodiments according to the present disclosure. Referring to FIG. 6, the respective scan unit in some embodiments includes a first subcircuit SC1, a second subcircuit SC2, a third subcircuit SC3, a fourth subcircuit SC4, and a fifth subcircuit SC5.

In some embodiments, the first subcircuit SC1 is configured to receive an input signal from an input terminal Ei. The input terminal Ei is configured to receive a start signal or an output signal from an output terminal of a previous scan unit (e.g., a (n−1)-th scan unit SU(n−1), a (n−2)-th scan unit, or a (n−3)-th scan unit). As used herein, the term “previous scan unit” is not limited to immediately previous scan unit (e.g., the (n−1)-th scan unit), but includes any appropriate previous scan unit (e.g., the (n−2)-th scan unit, or the (n−3)-th scan unit). In some embodiments, the first subcircuit SC1 is connected to a first node N1.

In some embodiments, the second subcircuit SC2 is connected to the first node N1, connected to a second node N2.

In some embodiments, the third subcircuit SC3 is connected to the second node N2, and connected to a third node N3.

In some embodiments, the fourth subcircuit SC4 is connected to a fourth node N4, and connected to a sixth node N6.

In some embodiments, the fifth subcircuit SC5 is configured to output an output signal through an output terminal OUT. In some embodiments, the fifth subcircuit SC5 is connected to the fourth node N4.

In some embodiments, the first subcircuit SC1 includes an input transistor T1, a thirteenth transistor T13, a fourteenth transistor T14, and a fifteenth transistor T15.

A gate electrode of the thirteenth transistor T13 is configured to receive a third clock signal from a third clock terminal CLK3. A first electrode of the thirteenth transistor T13 is configured to receive an input signal from an input terminal Ei. A second electrode of the thirteenth transistor T13 is connected to a first electrode of the input transistor T1.

A gate electrode of the input transistor T1 is configured to receive a second clock signal from a second clock terminal CLK2. A first electrode of the input transistor T1 is connected to a second electrode of the thirteenth transistor T13. A second electrode of the input transistor T1 is connected to a first node N1.

A gate electrode of the fourteenth transistor T14 is configured to receive an enabling control signal VEL. A first electrode of the fourteenth transistor T14 is configured to receive a second reference voltage signal from a second reference voltage terminal VGH2. A second electrode of the fourteenth transistor T14 is connected to the first node N1.

A gate electrode of the fifteenth transistor T15 is configured to receive a fourth reference voltage signal from a fourth reference voltage terminal VGL1. A first electrode of the fifteenth transistor T15 is connected to the first node N1. A second electrode of the fifteenth transistor T15 is connected to the sixth node N6.

In some embodiments, the second subcircuit SC2 includes a first transistor T1, a fourth transistor T4, a seventh transistor T7, and a first capacitor C1. A gate electrode of the first transistor T1 is connected to the first node N1. A first electrode of the first transistor T1 is configured to receive the second clock signal from the second clock terminal CLK2. A second electrode of the first transistor T1 is connected to a second node N2.

A gate electrode of the fourth transistor T4 is connected to the sixth node N6. A first electrode of the fourth transistor T4 is configured to receive a first clock signal from a first clock terminal CLK1. A second electrode of the fourth transistor T4 is connected to a fifth node N5.

A gate electrode of the seventh transistor T7 is connected to the second node N2. A first electrode of the seventh transistor T7 is configured to receive the second reference voltage signal from the second reference voltage terminal VGH2. A second electrode of the seventh transistor T7 is connected to the fifth node N5.

A first electrode of the first capacitor C1 is connected to the sixth node N6. A second electrode of the first capacitor C1 is connected to the fifth node N5.

In some embodiments, the third subcircuit SC3 includes a sixth transistor T6, a ninth transistor T9, a tenth transistor T10, and a second capacitor C2. A gate electrode of the sixth transistor T6 is configured to receive the third clock signal from the third clock terminal CLK3. A first electrode of the sixth transistor T6 is configured to receive a third reference voltage signal from a third reference voltage terminal VGL. A second electrode of the sixth transistor T6 is connected to the second node N2.

A gate electrode of the ninth transistor T9 is connected to the second node N2. A first electrode of the ninth transistor T9 is configured to receive the first clock signal from the first clock terminal CLK1. A second electrode of the ninth transistor T9 is connected to a third node N3.

A gate electrode of the tenth transistor T10 is configured to receive the first clock signal from the first clock terminal CLK1. A first electrode of the tenth transistor T10 is connected to the third node N3. A second electrode of the tenth transistor T10 is connected to a fourth node N4.

A first electrode of the second capacitor C2 is connected to the second node N2. A second electrode of the second capacitor C2 is connected to the third node N3.

In some embodiments, the fourth subcircuit SC4 includes a fifth transistor T5, an eighth transistor T8, and a fourth capacitor C4. A gate electrode of the fifth transistor T5 is connected to a sixth node N6. A first electrode of the fifth transistor T5 is configured to receive the third reference voltage signal from the third reference voltage terminal VGL. A second electrode of the fifth transistor T5 is connected to an output terminal OUT.

A gate electrode of the eighth transistor T8 is connected to a sixth node N6. A first electrode of the eighth transistor T8 is configured to receive the third clock signal from the third clock terminal CLK3. A second electrode of the eighth transistor T8 is connected to the fourth node N4.

In some embodiments, the first reference voltage signal, the second reference voltage signal, the third reference voltage signal, and the fourth reference voltage signal are different from each other. In some embodiments, the first reference voltage signal, the second reference voltage signal, the third reference voltage signal, and the fourth reference voltage signal are constant voltage signals. In some embodiments, the first reference voltage signal has a voltage level higher than a voltage level of the third reference voltage signal. In some embodiments, the second reference voltage signal has a voltage level higher than a voltage level of the third reference voltage signal. In some embodiments, the first reference voltage signal has a voltage level higher than a voltage level of the fourth reference voltage signal. In some embodiments, the second reference voltage signal has a voltage level higher than a voltage level of the fourth reference voltage signal.

A first electrode of the fourth capacitor C4 is configured to receive the third reference voltage signal from the third reference voltage terminal VGL. A second electrode of the fourth capacitor C4 is connected to the sixth node N6.

In some embodiments, the fifth subcircuit SC5 includes an output transistor To and a third capacitor C3. A gate electrode of the output transistor To is connected to the fourth node N4. A first electrode of the output transistor To is configured to receive the third clock signal from the third clock terminal (alternatively, the first reference voltage signal from the first reference voltage terminal VGH). A second electrode of the output transistor To is connected to the output terminal OUT.

A first electrode of the third capacitor C3 is connected to the fourth node N4. A second electrode of the third capacitor C3 is configured to receive the third clock signal from the third clock terminal (alternatively, the first reference voltage signal from the first reference voltage terminal VGH).

The inventors of the present disclosure discover that, by having the thirteenth transistor T13, the fourteenth transistor T14, and the fifteenth transistor T15 in the first subcircuit, the effect of low level signal on the input transistor Ti can be mitigated. The thirteenth transistor T13 is placed in front of the input transistor Ti, where the gate electrode of the input transistor T1 is connected to the second clock terminal CLK2, and the gate electrode of the thirteenth transistor T13 is connected to the third clock terminal CLK3. The main function of the thirteenth transistor T13 is to isolate the effect of the low level signal on the input transistor T1.

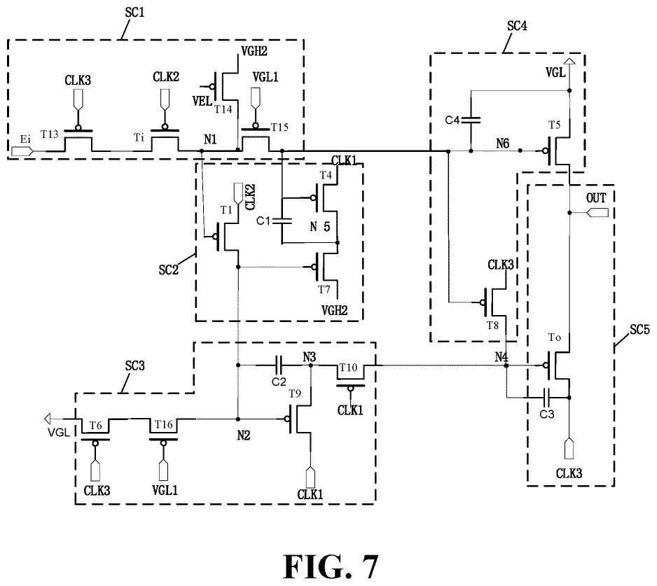

FIG. 7 is a circuit diagram of a respective scan unit in some embodiments according to the present disclosure. Referring to FIG. 7, the respective scan unit in some embodiments includes a first subcircuit SC1, a second subcircuit SC2, a third subcircuit SC3, a fourth subcircuit SC4, and a fifth subcircuit SC5.

In some embodiments, the first subcircuit SC1 is configured to receive an input signal from an input terminal Ei. The input terminal Ei is configured to receive a start signal or an output signal from an output terminal of a previous scan unit (e.g., a (n−1)-th scan unit SU(n−1), a (n−2)-th scan unit, or a (n−3)-th scan unit). As used herein, the term “previous scan unit” is not limited to immediately previous scan unit (e.g., the (n−1)-th scan unit), but includes any appropriate previous scan unit (e.g., the (n−2)-th scan unit, or the (n−3)-th scan unit). In some embodiments, the first subcircuit SC1 is connected to a first node N1.

In some embodiments, the second subcircuit SC2 is connected to the first node N1, connected to a second node N2.

In some embodiments, the third subcircuit SC3 is connected to the second node N2, and connected to a third node N3.

In some embodiments, the fourth subcircuit SC4 is connected to a fourth node N4, and connected to a sixth node N6.

In some embodiments, the fifth subcircuit SC5 is configured to output an output signal through an output terminal OUT. In some embodiments, the fifth subcircuit SC5 is connected to the fourth node N4.

In some embodiments, the first subcircuit SC1 includes an input transistor T1, a thirteenth transistor T13, a fourteenth transistor T14, and a fifteenth transistor T15.

A gate electrode of the thirteenth transistor T13 is configured to receive a third clock signal from a third clock terminal CLK3. A first electrode of the thirteenth transistor T13 is configured to receive an input signal from an input terminal Ei. A second electrode of the thirteenth transistor T13 is connected to a first electrode of the input transistor T1.

A gate electrode of the input transistor T1 is configured to receive a second clock signal from a second clock terminal CLK2. A first electrode of the input transistor T1 is connected to a second electrode of the thirteenth transistor T13. A second electrode of the input transistor T1 is connected to a first node N1.

A gate electrode of the fourteenth transistor T14 is configured to receive an enabling control signal VEL. A first electrode of the fourteenth transistor T14 is configured to receive a second reference voltage signal from a second reference voltage terminal VGH2. A second electrode of the fourteenth transistor T14 is connected to the first node N1.

A gate electrode of the fifteenth transistor T15 is configured to receive a fourth reference voltage signal from a fourth reference voltage terminal VGL1. A first electrode of the fifteenth transistor T15 is connected to the first node N1. A second electrode of the fifteenth transistor T15 is connected to the sixth node N6.

In some embodiments, the second subcircuit SC2 includes a first transistor T1, a fourth transistor T4, a seventh transistor T7, and a first capacitor C1. A gate electrode of the first transistor T1 is connected to the first node N1. A first electrode of the first transistor T1 is configured to receive the second clock signal from the second clock terminal CLK2. A second electrode of the first transistor T1 is connected to a second node N2.

A gate electrode of the fourth transistor T4 is connected to the sixth node N6. A first electrode of the fourth transistor T4 is configured to receive a first clock signal from a first clock terminal CLK1. A second electrode of the fourth transistor T4 is connected to a fifth node N5.

A gate electrode of the seventh transistor T7 is connected to the second node N2. A first electrode of the seventh transistor T7 is configured to receive the second reference voltage signal from the second reference voltage terminal VGH2. A second electrode of the seventh transistor T7 is connected to the fifth node N5.

A first electrode of the first capacitor C1 is connected to the sixth node N6. A second electrode of the first capacitor C1 is connected to the fifth node N5.

In some embodiments, the third subcircuit SC3 includes a sixth transistor T6, a ninth transistor T9, a tenth transistor T10, a sixteenth transistor T16, and a second capacitor C2.

A gate electrode of the sixth transistor T6 is configured to receive the third clock signal from the third clock terminal CLK3. A first electrode of the sixth transistor T6 is configured to receive a third reference voltage signal from a third reference voltage terminal VGL. A second electrode of the sixth transistor T6 is connected to a first electrode of the sixteenth transistor T16.

In the respective scan unit depicted in FIG. 4, the first electrode of the sixth transistor T6 is configured to receive a third reference voltage signal from a third reference voltage terminal VGL, e.g., a low level voltage signal for an extended period, which may cause the threshold voltage of the sixth transistor to shift. The inventors of the present disclosure discover that, by having a sixteenth transistor T16, the effect of low level signal on the sixth transistor T6 can be mitigated.

A gate electrode of the sixteenth transistor T16 is configured to receive the fourth reference voltage signal from the fourth reference voltage terminal VGL1. A first electrode of the sixteenth transistor T16 is connected to the second electrode of the sixth transistor T6. A second electrode of the sixteenth transistor T16 is connected to the second node N2. The sixteenth transistor T16 is configured to be turned on as long as the gate electrode of the sixteenth transistor T16 receives the fourth reference voltage signal (e.g., a low level voltage signal).

A gate electrode of the ninth transistor T9 is connected to the second node N2. A first electrode of the ninth transistor T9 is configured to receive the first clock signal from the first clock terminal CLK1. A second electrode of the ninth transistor T9 is connected to a third node N3.

A gate electrode of the tenth transistor T10 is configured to receive the first clock signal from the first clock terminal CLK1. A first electrode of the tenth transistor T10 is connected to the third node N3. A second electrode of the tenth transistor T10 is connected to a fourth node N4.

A first electrode of the second capacitor C2 is connected to the second node N2. A second electrode of the second capacitor C2 is connected to the third node N3.

In some embodiments, the fourth subcircuit SC4 includes a fifth transistor T5, an eighth transistor T8, and a fourth capacitor C4. A gate electrode of the fifth transistor T5 is connected to a sixth node N6. A first electrode of the fifth transistor T5 is configured to receive the third reference voltage signal from the third reference voltage terminal VGL. A second electrode of the fifth transistor T5 is connected to an output terminal OUT.

A gate electrode of the eighth transistor T8 is connected to a sixth node N6. A first electrode of the eighth transistor T8 is configured to receive the third clock signal from the third clock terminal CLK3. A second electrode of the eighth transistor T8 is connected to the fourth node N4.

In some embodiments, the first reference voltage signal, the second reference voltage signal, the third reference voltage signal, and the fourth reference voltage signal are different from each other. In some embodiments, the first reference voltage signal, the second reference voltage signal, the third reference voltage signal, and the fourth reference voltage signal are constant voltage signals. In some embodiments, the first reference voltage signal has a voltage level higher than a voltage level of the third reference voltage signal. In some embodiments, the second reference voltage signal has a voltage level higher than a voltage level of the third reference voltage signal. In some embodiments, the first reference voltage signal has a voltage level higher than a voltage level of the fourth reference voltage signal. In some embodiments, the second reference voltage signal has a voltage level higher than a voltage level of the fourth reference voltage signal.

A first electrode of the fourth capacitor C4 is configured to receive the third reference voltage signal from the third reference voltage terminal VGL. A second electrode of the fourth capacitor C4 is connected to the sixth node N6.

In some embodiments, the fifth subcircuit SC5 includes an output transistor To and a third capacitor C3. A gate electrode of the output transistor To is connected to the fourth node N4. A first electrode of the output transistor To is configured to receive the third clock signal from the third clock terminal (alternatively, the first reference voltage signal from the first reference voltage terminal VGH). A second electrode of the output transistor To is connected to the output terminal OUT.

A first electrode of the third capacitor C3 is connected to the fourth node N4. A second electrode of the third capacitor C3 is configured to receive the third clock signal from the third clock terminal (alternatively, the first reference voltage signal from the first reference voltage terminal VGH).

The inventors of the present disclosure discover that, by having the thirteenth transistor T13, the fourteenth transistor T14, and the fifteenth transistor T15 in the first subcircuit, the effect of low level signal on the input transistor Ti can be mitigated. The thirteenth transistor T13 is placed in front of the input transistor Ti, where the gate electrode of the input transistor T1 is connected to the second clock terminal CLK2, and the gate electrode of the thirteenth transistor T13 is connected to the third clock terminal CLK3. The main function of the thirteenth transistor T13 is to isolate the effect of the low level signal on the input transistor T1.

In some embodiments, the scan circuit is configured to receive four clock signals from four different clock signal lines, respectively. In comparison, a related scan circuit is configured to receive two clock signals from two different clock signal lines, respectively. The scan circuit according to the present disclosure can save power consumption.

In some embodiments, a dynamic power consumption formula is given as:

$$P = \frac{1}{2} f {CV}^{2} ;$$

wherein f is the signal frequency, C is the total capacitance, and V is the transition voltage.

When the related scan circuit is configured to receive two clock signals from two different clock signal lines, respectively,

$$P ( 2 CK ) = 2 * \frac{1}{2} f ( 2 CK ) C ( 2 CK ) {V ( 2 CK )}^{2} .$$

When the scan circuit is configured to receive four clock signals from four different clock signal lines, respectively,

$$f ( 4 CK ) = \frac{1}{2} f ( 2 CK ) , C ( 4 CK ) \approx 0.7 C ( 2 CK ) , V ( 4 CK ) = V ( 2 CK ) .$$

$$Ideally , C ( 4 CK ) = 0.5 C ( 2 CK ) .$$

In real case scenario, due to layout complexities, C(4CK) typically falls within the range of 0.6 to 0.8.

Using a value of 0.7 for calculation,

$$P ( 4 CK ) = 4 * \frac{1}{2} f ( 4 CK ) C ( 4 CK ) {V ( 4 CK )}^{2} \approx 4 * \frac{1}{2} * \frac{1}{2} ( 2 CK ) * 0.7 * C ( 2 CK ) {V ( 2 CK )}^{2} = 0.7 * P ( 2 CK )$$

Therefore, the scan circuit according to the present disclosure can save approximately 30% to 50% of power consumption compared to the related scan circuit.

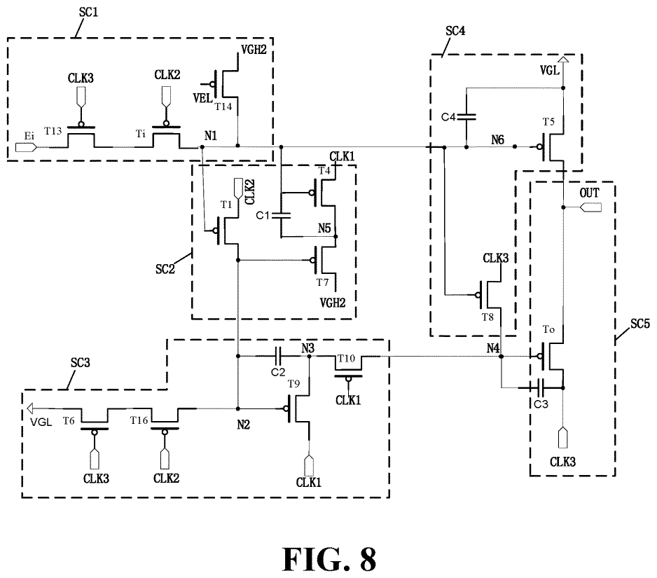

FIG. 8 is a circuit diagram of a respective scan unit in some embodiments according to the present disclosure. Referring to FIG. 8, the respective scan unit in some embodiments includes a first subcircuit SC1, a second subcircuit SC2, a third subcircuit SC3, a fourth subcircuit SC4, and a fifth subcircuit SC5.

In some embodiments, the first subcircuit SC1 is configured to receive an input signal from an input terminal Ei. The input terminal Ei is configured to receive a start signal or an output signal from an output terminal of a previous scan unit (e.g., a (n−1)-th scan unit SU(n−1), a (n−2)-th scan unit, or a (n−3)-th scan unit). As used herein, the term “previous scan unit” is not limited to immediately previous scan unit (e.g., the (n−1)-th scan unit), but includes any appropriate previous scan unit (e.g., the (n−2)-th scan unit, or the (n−3)-th scan unit). In some embodiments, the first subcircuit SC1 is connected to a first node N1.

In some embodiments, the second subcircuit SC2 is connected to the first node N1, connected to a second node N2.

In some embodiments, the third subcircuit SC3 is connected to the second node N2, and connected to a third node N3.

In some embodiments, the fourth subcircuit SC4 is connected to a fourth node N4, and connected to a sixth node N6.

In some embodiments, the fifth subcircuit SC5 is configured to output an output signal through an output terminal OUT. In some embodiments, the fifth subcircuit SC5 is connected to the fourth node N4.

In some embodiments, the first subcircuit SC1 includes an input transistor T1, a thirteenth transistor T13, and a fourteenth transistor T14.

A gate electrode of the thirteenth transistor T13 is configured to receive a third clock signal from a third clock terminal CLK3. A first electrode of the thirteenth transistor T13 is configured to receive an input signal from an input terminal Ei. A second electrode of the thirteenth transistor T13 is connected to a first electrode of the input transistor T1.

A gate electrode of the input transistor T1 is configured to receive a second clock signal from a second clock terminal CLK2. A first electrode of the input transistor T1 is connected to a second electrode of the thirteenth transistor T13. A second electrode of the input transistor T1 is connected to a first node N1.

A gate electrode of the fourteenth transistor T14 is configured to receive an enabling control signal VEL. A first electrode of the fourteenth transistor T14 is configured to receive a second reference voltage signal from a second reference voltage terminal VGH2. A second electrode of the fourteenth transistor T14 is connected to the first node N1.

In some embodiments, the second subcircuit SC2 includes a first transistor T1, a fourth transistor T4, a seventh transistor T7, and a first capacitor C1. A gate electrode of the first transistor T1 is connected to the first node N1. A first electrode of the first transistor T1 is configured to receive the second clock signal from the second clock terminal CLK2. A second electrode of the first transistor T1 is connected to a second node N2.

A gate electrode of the fourth transistor T4 is connected to the first node N1. A first electrode of the fourth transistor T4 is configured to receive a first clock signal from a first clock terminal CLK1. A second electrode of the fourth transistor T4 is connected to a fifth node N5.

A gate electrode of the seventh transistor T7 is connected to the second node N2. A first electrode of the seventh transistor T7 is configured to receive the second reference voltage signal from the second reference voltage terminal VGH2. A second electrode of the seventh transistor T7 is connected to the fifth node N5.

A first electrode of the first capacitor C1 is connected to the first node N1. A second electrode of the first capacitor C1 is connected to the fifth node N5.

In some embodiments, the third subcircuit SC3 includes a sixth transistor T6, a ninth transistor T9, a tenth transistor T10, a sixteenth transistor T16, and a second capacitor C2.

A gate electrode of the sixth transistor T6 is configured to receive the third clock signal from the third clock terminal CLK3. A first electrode of the sixth transistor T6 is configured to receive a third reference voltage signal from a third reference voltage terminal VGL. A second electrode of the sixth transistor T6 is connected to a first electrode of the sixteenth transistor T16.

A gate electrode of the sixteenth transistor T16 is configured to receive the second clock signal from the second clock terminal CLK2. A first electrode of the sixteenth transistor T16 is connected to the second electrode of the sixth transistor T6. A second electrode of the sixteenth transistor T16 is connected to the second node N2. The sixteenth transistor T16 is configured to be turned on as long as the gate electrode of the sixteenth transistor T16 receives the fourth reference voltage signal (e.g., a low level voltage signal).

In the respective scan unit depicted in FIG. 4, the first electrode of the sixth transistor T6 is configured to receive a third reference voltage signal from a third reference voltage terminal VGL, e.g., a low level voltage signal for an extended period, which may cause the threshold voltage of the sixth transistor to shift. The inventors of the present disclosure discover that, by having a sixteenth transistor T16, the effect of low level signal on the sixth transistor T6 can be mitigated.

A gate electrode of the ninth transistor T9 is connected to the second node N2. A first electrode of the ninth transistor T9 is configured to receive the first clock signal from the first clock terminal CLK1. A second electrode of the ninth transistor T9 is connected to a third node N3.

A gate electrode of the tenth transistor T10 is configured to receive the first clock signal from the first clock terminal CLK1. A first electrode of the tenth transistor T10 is connected to the third node N3. A second electrode of the tenth transistor T10 is connected to a fourth node N4.

A first electrode of the second capacitor C2 is connected to the second node N2. A second electrode of the second capacitor C2 is connected to the third node N3.

In some embodiments, the fourth subcircuit SC4 includes a fifth transistor T5, an eighth transistor T8, and a fourth capacitor C4. A gate electrode of the fifth transistor T5 is connected to a sixth node N6. A first electrode of the fifth transistor T5 is configured to receive the third reference voltage signal from the third reference voltage terminal VGL. A second electrode of the fifth transistor T5 is connected to an output terminal OUT.

A gate electrode of the eighth transistor T8 is connected to a sixth node N6. A first electrode of the eighth transistor T8 is configured to receive the third clock signal from the third clock terminal CLK3. A second electrode of the eighth transistor T8 is connected to the fourth node N4.

In some embodiments, the first reference voltage signal, the second reference voltage signal, the third reference voltage signal, and the fourth reference voltage signal are different from each other. In some embodiments, the first reference voltage signal, the second reference voltage signal, the third reference voltage signal, and the fourth reference voltage signal are constant voltage signals. In some embodiments, the first reference voltage signal has a voltage level higher than a voltage level of the third reference voltage signal. In some embodiments, the second reference voltage signal has a voltage level higher than a voltage level of the third reference voltage signal. In some embodiments, the first reference voltage signal has a voltage level higher than a voltage level of the fourth reference voltage signal. In some embodiments, the second reference voltage signal has a voltage level higher than a voltage level of the fourth reference voltage signal.

A first electrode of the fourth capacitor C4 is configured to receive the third reference voltage signal from the third reference voltage terminal VGL. A second electrode of the fourth capacitor C4 is connected to the sixth node N6. In the respective scan unit depicted in FIG. 8, the first node N1 and the sixth node N6 are electrically connected without any intervening transistor or capacitor.

In some embodiments, the fifth subcircuit SC5 includes an output transistor To and a third capacitor C3. A gate electrode of the output transistor To is connected to the fourth node N4. A first electrode of the output transistor To is configured to receive the third clock signal from the third clock terminal (alternatively, the first reference voltage signal from the first reference voltage terminal VGH). A second electrode of the output transistor To is connected to the output terminal OUT.

A first electrode of the third capacitor C3 is connected to the fourth node N4. A second electrode of the third capacitor C3 is configured to receive the third clock signal from the third clock terminal (alternatively, the first reference voltage signal from the first reference voltage terminal VGH).

The inventors of the present disclosure discover that, by having the thirteenth transistor T13, the fourteenth transistor T14, and the fifteenth transistor T15 in the first subcircuit, the effect of low level signal on the input transistor Ti can be mitigated. The thirteenth transistor T13 is placed in front of the input transistor Ti, where the gate electrode of the input transistor T1 is connected to the second clock terminal CLK2, and the gate electrode of the thirteenth transistor T13 is connected to the third clock terminal CLK3. The main function of the thirteenth transistor T13 is to isolate the effect of the low level signal on the input transistor T1.

In the respective scan unit depicted in FIG. 4, the first electrode of the sixth transistor T6 is configured to receive a third reference voltage signal from a third reference voltage terminal VGL, e.g., a low level voltage signal for an extended period, which may cause the threshold voltage of the sixth transistor to shift. The inventors of the present disclosure discover that, by having a sixteenth transistor T16, the effect of low level signal on the sixth transistor T6 can be mitigated.

In alternative embodiments, the gate electrode of the sixth transistor T6 is configured to receive the second clock signal from the second clock terminal CLK2, and the gate electrode of the sixteenth transistor T16 is configured to receive the third clock signal from the third clock terminal CLK3.

In alternative embodiments, the first subcircuit SC1 further includes a fifteenth transistor T15. A gate electrode of the fifteenth transistor T15 is configured to receive a fourth reference voltage signal from a fourth reference voltage terminal VGL1. A first electrode of the fifteenth transistor T15 is connected to the first node N1. A second electrode of the fifteenth transistor T15 is connected to the sixth node N6.

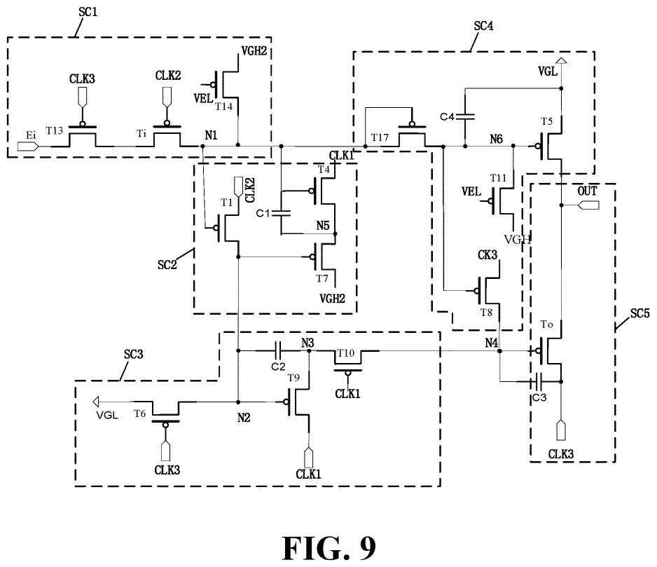

FIG. 9 is a circuit diagram of a respective scan unit in some embodiments according to the present disclosure. Referring to FIG. 9, the respective scan unit in some embodiments includes a first subcircuit SC1, a second subcircuit SC2, a third subcircuit SC3, a fourth subcircuit SC4, and a fifth subcircuit SC5.

In some embodiments, the first subcircuit SC1 is configured to receive an input signal from an input terminal Ei. The input terminal Ei is configured to receive a start signal or an output signal from an output terminal of a previous scan unit (e.g., a (n−1)-th scan unit SU(n−1), a (n−2)-th scan unit, or a (n−3)-th scan unit).

In some embodiments, the second subcircuit SC2 is connected to the first node N1, and connected to a second node N2.

In some embodiments, the third subcircuit SC3 is connected to the second node N2, and connected to a third node N3.

In some embodiments, the fourth subcircuit SC4 is connected to a fourth node N4, and connected to a sixth node N6.

In some embodiments, the fifth subcircuit SC5 is configured to output an output signal through an output terminal OUT. In some embodiments, the fifth subcircuit SC5 is connected to the fourth node N4.

In some embodiments, the first subcircuit SC1 includes an input transistor T1, a thirteenth transistor T13, and a fourteenth transistor T14.

A gate electrode of the thirteenth transistor T13 is configured to receive a third clock signal from a third clock terminal CLK3. A first electrode of the thirteenth transistor T13 is configured to receive an input signal from an input terminal Ei. A second electrode of the thirteenth transistor T13 is connected to a first electrode of the input transistor T1.

A gate electrode of the input transistor T1 is configured to receive a second clock signal from a second clock terminal CLK2. A first electrode of the input transistor T1 is connected to a second electrode of the thirteenth transistor T13. A second electrode of the input transistor T1 is connected to a first node N1.

A gate electrode of the fourteenth transistor T14 is configured to receive an enabling control signal. A first electrode of the fourteenth transistor T14 is configured to receive a second reference voltage signal from a second reference voltage terminal VGH2. A second electrode of the fourteenth transistor T14 is connected to the first node N1.

In some embodiments, the second subcircuit SC2 includes a first transistor T1, a fourth transistor T4, a seventh transistor T7, and a first capacitor C1. A gate electrode of the first transistor T1 is connected to the first node N1. A first electrode of the first transistor T1 is configured to receive the second clock signal from the second clock terminal CLK2. A second electrode of the first transistor T1 is connected to a second node N2.

A gate electrode of the fourth transistor T4 is connected to the first node N1. A first electrode of the fourth transistor T4 is configured to receive a first clock signal from a first clock terminal CLK1. A second electrode of the fourth transistor T4 is connected to a fifth node N5.

A gate electrode of the seventh transistor T7 is connected to the second node N2. A first electrode of the seventh transistor T7 is configured to receive the second reference voltage signal from the second reference voltage terminal VGH2. A second electrode of the seventh transistor T7 is connected to the fifth node N5.

A first electrode of the first capacitor C1 is connected to the first node N1. A second electrode of the first capacitor C1 is connected to the fifth node N5.

In some embodiments, the third subcircuit SC3 includes a sixth transistor T6, a ninth transistor T9, a tenth transistor T10, and a second capacitor C2. A gate electrode of the sixth transistor T6 is configured to receive the third clock signal from the third clock terminal CLK3. A first electrode of the sixth transistor T6 is configured to receive a third reference voltage signal from a third reference voltage terminal VGL. A second electrode of the sixth transistor T6 is connected to the second node N2.

A gate electrode of the ninth transistor T9 is connected to the second node N2. A first electrode of the ninth transistor T9 is configured to receive the first clock signal from the first clock terminal CLK1. A second electrode of the ninth transistor T9 is connected to a third node N3.

A gate electrode of the tenth transistor T10 is configured to receive the first clock signal from the first clock terminal CLK1. A first electrode of the tenth transistor T10 is connected to the third node N3. A second electrode of the tenth transistor T10 is connected to a fourth node N4.

A first electrode of the second capacitor C2 is connected to the second node N2. A second electrode of the second capacitor C2 is connected to the third node N3.

In some embodiments, the fourth subcircuit SC4 includes a fifth transistor T5, an eighth transistor T8, an eleventh transistor T11, a seventeenth transistor T17, and a fourth capacitor C4. A gate electrode of the fifth transistor T5 is connected to a sixth node N6. A first electrode of the fifth transistor T5 is configured to receive the third reference voltage signal from the third reference voltage terminal VGL. A second electrode of the fifth transistor T5 is connected to an output terminal OUT.

A gate electrode of the eighth transistor T8 is connected to a sixth node N6. A first electrode of the eighth transistor T8 is configured to receive the third clock signal from the third clock terminal CLK3. A second electrode of the eighth transistor T8 is connected to the fourth node N4.

In some embodiments, the first reference voltage signal, the second reference voltage signal, and the third reference voltage signal are different from each other. In some embodiments, the first reference voltage signal, the second reference voltage signal, and the third reference voltage signal are constant voltage signals. In some embodiments, the first reference voltage signal has a voltage level higher than a voltage level of the third reference voltage signal. In some embodiments, the second reference voltage signal has a voltage level higher than a voltage level of the third reference voltage signal.

A first electrode of the fourth capacitor C4 is configured to receive the third reference voltage signal from the third reference voltage terminal VGL. A second electrode of the fourth capacitor C4 is connected to the sixth node N6. In the respective scan unit depicted in FIG. 9, the first node N1 and the sixth node N6 are electrically isolated by the seventeenth transistor T17.

A gate electrode of the eleventh transistor T11 is configured to receive an enabling control signal VEL. A first electrode of the eleventh transistor T11 is configured to receive a first reference voltage signal from a first reference voltage terminal VGH. A second electrode of the eleventh transistor T11 is connected to the sixth node N6.

A gate electrode and a first electrode of the seventeenth transistor T17 are connected to the first node N1. A second electrode of the seventeenth transistor T17 is connected to the sixth node N6.

In some embodiments, the fifth subcircuit SC5 includes an output transistor To and a third capacitor C3. A gate electrode of the output transistor To is connected to the fourth node N4. A first electrode of the output transistor To is configured to receive the third clock signal from the third clock terminal (alternatively, the first reference voltage signal from the first reference voltage terminal VGH). A second electrode of the output transistor To is connected to the output terminal OUT.

A first electrode of the third capacitor C3 is connected to the fourth node N4. A second electrode of the third capacitor C3 is configured to receive the third clock signal from the third clock terminal (alternatively, the first reference voltage signal from the first reference voltage terminal VGH).

The inventors of the present disclosure discover that, by having the thirteenth transistor T13 and the fourteenth transistor T14 in the first subcircuit, the effect of low level signal on the input transistor Ti can be mitigated. The thirteenth transistor T13 is placed in front of the input transistor Ti, where the gate electrode of the input transistor T1 is connected to the second clock terminal CLK2, and the gate electrode of the thirteenth transistor T13 is connected to the third clock terminal CLK3. The main function of the thirteenth transistor T13 is to isolate the effect of the low level signal on the input transistor T1.

The inventors of the present disclosure discover that, by having a charge pump (e.g., the seventeenth transistor T17) and the eleventh transistor controlled by the enabling control signal VEL, the voltage level at the sixth node N6 can be stabilized, ensuring stable output. The inclusion of the charge pump helps to further stabilize the low voltage at the sixth node N6, making the output of the fifth transistor T5 more stable when providing the third reference voltage signal.

The inventors of the present disclosure further discover that, when the first node N1 transitions from a low level to a high level, the charge pump may shut off, potentially causing the low voltage at the sixth node N6 to not dissipate in time, which could unintentionally turn on the fifth transistor T5. To prevent this, a stabilization transistor (e.g., the eleventh transistor T11) can be added at the sixth node N6. Under the control of the enabling control signal VEL, this ensures that when the charge pump is turned off, the gate of the fifth transistor T5 remains at a high voltage, keeping the fifth transistor T5 turning off.

In some embodiments, the enabling control signal VEL for the eleventh transistor T11 may be the same as the enabling control signal VEL for the fourteenth transistor T14. In alternative embodiments, the enabling control signal VEL for the eleventh transistor T11 is different from the enabling control signal VEL for the fourteenth transistor T14.

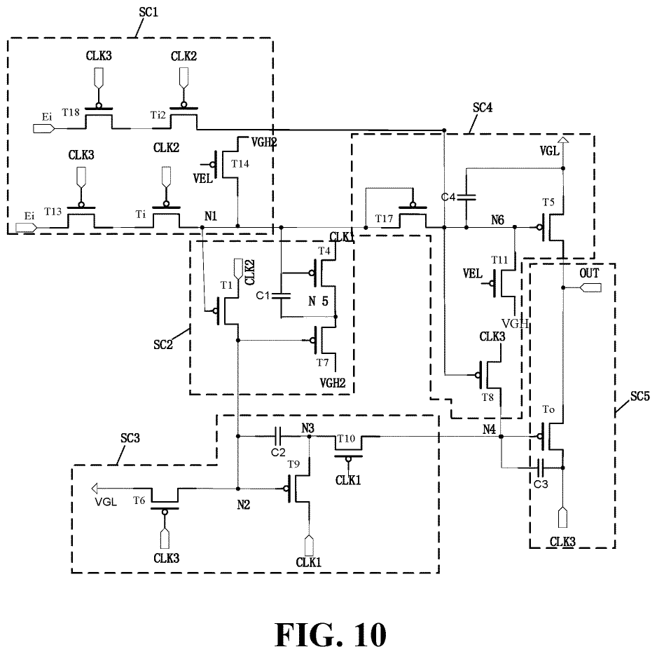

FIG. 10 is a circuit diagram of a respective scan unit in some embodiments according to the present disclosure. Referring to FIG. 10, the respective scan unit in some embodiments includes a first subcircuit SC1, a second subcircuit SC2, a third subcircuit SC3, a fourth subcircuit SC4, and a fifth subcircuit SC5.

In some embodiments, the first subcircuit SC1 is configured to receive an input signal from an input terminal Ei. The input terminal Ei is configured to receive a start signal or an output signal from an output terminal of a previous scan unit (e.g., a (n−1)-th scan unit SU(n−1), a (n−2)-th scan unit, or a (n−3)-th scan unit).

In some embodiments, the second subcircuit SC2 is connected to the first node N1, and connected to a second node N2.

In some embodiments, the third subcircuit SC3 is connected to the second node N2, and connected to a third node N3.

In some embodiments, the fourth subcircuit SC4 is connected to a fourth node N4, and connected to a sixth node N6.

In some embodiments, the fifth subcircuit SC5 is configured to output an output signal through an output terminal OUT. In some embodiments, the fifth subcircuit SC5 is connected to the fourth node N4.

In some embodiments, the first subcircuit SC1 includes an input transistor T1, a second input transistor Ti2, a thirteenth transistor T13, a fourteenth transistor T14, and an eighteenth transistor T18.

A gate electrode of the thirteenth transistor T13 is configured to receive a third clock signal from a third clock terminal CLK3. A first electrode of the thirteenth transistor T13 is configured to receive an input signal from an input terminal Ei. A second electrode of the thirteenth transistor T13 is connected to a first electrode of the input transistor T1.

A gate electrode of the input transistor T1 is configured to receive a second clock signal from a second clock terminal CLK2. A first electrode of the input transistor T1 is connected to a second electrode of the thirteenth transistor T13. A second electrode of the input transistor T1 is connected to a first node N1.

A gate electrode of the eighteenth transistor T18 is configured to receive a third clock signal from a third clock terminal CLK3. A first electrode of the eighteenth transistor T18 is configured to receive an input signal from an input terminal Ei. A second electrode of the eighteenth transistor T18 is connected to a first electrode of the second input transistor Ti2.

A gate electrode of the second input transistor Ti2 is configured to receive a second clock signal from a second clock terminal CLK2. A first electrode of the second input transistor Ti2 is connected to a second electrode of the eighteenth transistor T18. A second electrode of the second input transistor Ti2 is connected to a sixth node N6.

A gate electrode of the fourteenth transistor T14 is configured to receive an enabling control signal. A first electrode of the fourteenth transistor T14 is configured to receive a second reference voltage signal from a second reference voltage terminal VGH2. A second electrode of the fourteenth transistor T14 is connected to the first node N1.

In some embodiments, the second subcircuit SC2 includes a first transistor T1, a fourth transistor T4, a seventh transistor T7, and a first capacitor C1. A gate electrode of the first transistor T1 is connected to the first node N1. A first electrode of the first transistor T1 is configured to receive the second clock signal from the second clock terminal CLK2. A second electrode of the first transistor T1 is connected to a second node N2.

A gate electrode of the fourth transistor T4 is connected to the first node N1. A first electrode of the fourth transistor T4 is configured to receive a first clock signal from a first clock terminal CLK1. A second electrode of the fourth transistor T4 is connected to a fifth node N5.

A gate electrode of the seventh transistor T7 is connected to the second node N2. A first electrode of the seventh transistor T7 is configured to receive the second reference voltage signal from the second reference voltage terminal VGH2. A second electrode of the seventh transistor T7 is connected to the fifth node N5.

A first electrode of the first capacitor C1 is connected to the first node N1. A second electrode of the first capacitor C1 is connected to the fifth node N5.

In some embodiments, the third subcircuit SC3 includes a sixth transistor T6, a ninth transistor T9, a tenth transistor T10, and a second capacitor C2. A gate electrode of the sixth transistor T6 is configured to receive the third clock signal from the third clock terminal CLK3. A first electrode of the sixth transistor T6 is configured to receive a third reference voltage signal from a third reference voltage terminal VGL. A second electrode of the sixth transistor T6 is connected to the second node N2.

A gate electrode of the ninth transistor T9 is connected to the second node N2. A first electrode of the ninth transistor T9 is configured to receive the first clock signal from the first clock terminal CLK1. A second electrode of the ninth transistor T9 is connected to a third node N3.

A gate electrode of the tenth transistor T10 is configured to receive the first clock signal from the first clock terminal CLK1. A first electrode of the tenth transistor T10 is connected to the third node N3. A second electrode of the tenth transistor T10 is connected to a fourth node N4.

A first electrode of the second capacitor C2 is connected to the second node N2. A second electrode of the second capacitor C2 is connected to the third node N3.

In some embodiments, the fourth subcircuit SC4 includes a fifth transistor T5, an eighth transistor T8, an eleventh transistor T11, a seventeenth transistor T17, and a fourth capacitor C4. A gate electrode of the fifth transistor T5 is connected to a sixth node N6. A first electrode of the fifth transistor T5 is configured to receive the third reference voltage signal from the third reference voltage terminal VGL. A second electrode of the fifth transistor T5 is connected to an output terminal OUT.

A gate electrode of the eighth transistor T8 is connected to a sixth node N6. A first electrode of the eighth transistor T8 is configured to receive the third clock signal from the third clock terminal CLK3. A second electrode of the eighth transistor T8 is connected to the fourth node N4.

In some embodiments, the first reference voltage signal, the second reference voltage signal, and the third reference voltage signal are different from each other. In some embodiments, the first reference voltage signal, the second reference voltage signal, and the third reference voltage signal are constant voltage signals. In some embodiments, the first reference voltage signal has a voltage level higher than a voltage level of the third reference voltage signal. In some embodiments, the second reference voltage signal has a voltage level higher than a voltage level of the third reference voltage signal.

A first electrode of the fourth capacitor C4 is configured to receive the third reference voltage signal from the third reference voltage terminal VGL. A second electrode of the fourth capacitor C4 is connected to the sixth node N6. In the respective scan unit depicted in FIG. 10, the first node N1 and the sixth node N6 are electrically isolated by the seventeenth transistor T17.

A gate electrode of the eleventh transistor T11 is configured to receive an enabling control signal VEL. A first electrode of the eleventh transistor T11 is configured to receive the third clock signal from the third clock terminal CLK3 (alternatively, a first reference voltage signal from a first reference voltage terminal VGH). A second electrode of the eleventh transistor T11 is connected to the sixth node N6.

A gate electrode and a first electrode of the seventeenth transistor T17 are connected to the first node N1. A second electrode of the seventeenth transistor T17 is connected to the sixth node N6.

In some embodiments, the fifth subcircuit SC5 includes an output transistor To and a third capacitor C3. A gate electrode of the output transistor To is connected to the fourth node N4. A first electrode of the output transistor To is configured to receive the third clock signal from the third clock terminal CLK3 (alternatively, the first reference voltage signal from the first reference voltage terminal VGH). A second electrode of the output transistor To is connected to the output terminal OUT.

A first electrode of the third capacitor C3 is connected to the fourth node N4. A second electrode of the third capacitor C3 is configured to receive the third clock signal from the third clock terminal CLK3 (alternatively, the first reference voltage signal from the first reference voltage terminal VGH).

The inventors of the present disclosure discover that, by having the thirteenth transistor T13 and the fourteenth transistor T14 in the first subcircuit, the effect of low level signal on the input transistor Ti can be mitigated. The thirteenth transistor T13 is placed in front of the input transistor Ti, where the gate electrode of the input transistor T1 is connected to the second clock terminal CLK2, and the gate electrode of the thirteenth transistor T13 is connected to the third clock terminal CLK3. The main function of the thirteenth transistor T13 is to isolate the effect of the low level signal on the input transistor T1.

The inventors of the present disclosure discover that, by having a charge pump (e.g., the seventeenth transistor T17) and the eleventh transistor controlled by the enabling control signal VEL, the voltage level at the sixth node N6 can be stabilized, ensuring stable output. The inclusion of the charge pump helps to further stabilize the low voltage at the sixth node N6, making the output of the fifth transistor T5 more stable when providing the third reference voltage signal.

The inventors of the present disclosure further discover that, when the first node N1 transitions from a low level to a high level, the charge pump may shut off, potentially causing the low voltage at the sixth node N6 to not dissipate in time, which could unintentionally turn on the fifth transistor T5. To prevent this, a stabilization transistor (e.g., the eleventh transistor T11) can be added at the sixth node N6. Under the control of the enabling control signal VEL, this ensures that when the charge pump is turned off, the gate of the fifth transistor T5 remains at a high voltage, keeping the fifth transistor T5 turning off.

In some embodiments, the enabling control signal VEL for the eleventh transistor T11 may be the same as the enabling control signal VEL for the fourteenth transistor T14. In alternative embodiments, the enabling control signal VEL for the eleventh transistor T11 is different from the enabling control signal VEL for the fourteenth transistor T14.

In the respective scan unit depicted in FIG. 10, an additional signal path is added to the sixth node N6, including the eighteenth transistor T18 and the second input transistor Ti2. This structure enhances the signal input to the sixth node N6, ensuring a more stable output from the fifth transistor T5. For example, this configuration can be applied in mobile devices or larger-sized products, where maintaining stable signal transmission and output is critical for proper functioning and performance.

The inventors of the present disclosure discover that, by having dual routes feeding into the first node N1 and the sixth node N6, the respective scan unit can better handle fluctuations or interference, leading to improved stability, particularly in applications where precise control of the output signal is necessary, such as high-resolution displays in mobile phones or large-scale displays.

Referring to FIG. 6, FIG. 9, and FIG. 10, the gate electrode of the sixth transistor T6 is configured to receive a third clock signal from a third clock terminal CLK3. In alternative embodiments, the gate electrode of the sixth transistor T6 is configured to receive a second clock signal from a second clock terminal CLK2.

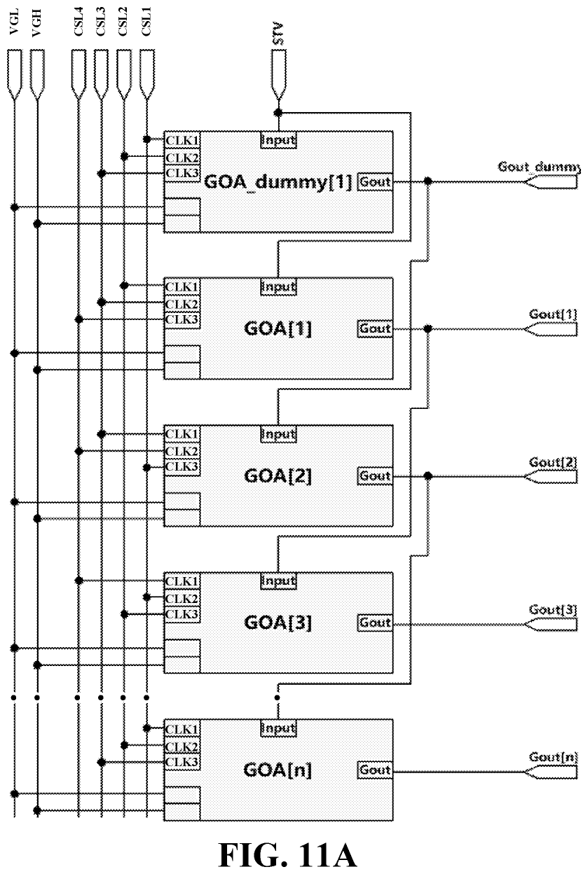

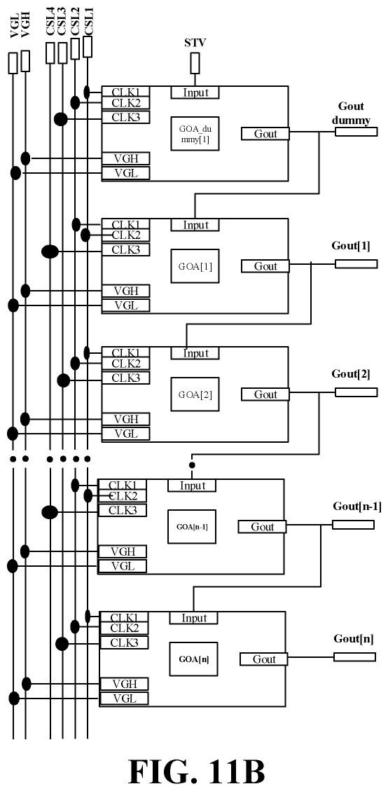

FIG. 11A is a schematic diagram of a scan circuit in some embodiments according to the present disclosure. Referring to FIG. 11A, the scan circuit in some embodiments includes a plurality of stages, a respective stage of the plurality of stages comprising a respective scan unit of a plurality of scan units. The scan circuit in some embodiments is configured to provide control signals to rows of subpixels in a display panel. Examples of control signals include gate scanning signals, reset control signals, and light emitting control signals. In one example, the scan circuit is a gate scanning signal scan circuit configured to provide gate scanning signals to the plurality of gate lines. In another example, the scan circuit is a light emitting control signal scan circuit configured to provide light emitting control signals to the plurality of light emitting control signal lines. In another example, the scan circuit is a reset control signal scan circuit configured to provide reset control signals to the plurality of reset control signal lines.

Referring to FIG. 11A, in some embodiments, the scan circuit includes n number of scan units cascaded. The n number of scan units include a first scan unit GOA[1], a second scan unit GOA[2], a third scan unit GOA[3], . . . , a n-th scan unit GOA[n]. Optionally, the scan circuit further includes a dummy unit GOA_dummy[1].

The scan circuit is configured to receive clock signals from a first clock signal line CSL1, a second clock signal line CSL2, a third clock signal line CSL3, and a fourth clock signal line CSL4, configured to receive a first reference voltage signal from a first reference voltage terminal VGH, and configured to receive a third reference voltage signal from a third reference voltage terminal VGL.

The dummy unit GOA_dummy[1] is configured to receive a start signal STV through an input terminal (“Input”), and configured to output an output signal Gout_dummy through an output terminal (“Gout”). The dummy unit GOA_dummy[1] is configured to receive a first clock signal from the first clock signal line CSL1 through a first clock terminal CLK1, a second clock signal from the second clock signal line CSL2 through a second clock terminal CLK2, a third clock signal from the third clock signal line CSL3 through a third clock terminal CLK3, the first reference voltage signal from the first reference voltage terminal VGH, and the third reference voltage signal from the third reference voltage terminal VGL.

The first scan unit GOA [1] is configured to receive the start signal STV through an input terminal (“Input”), and configured to output an output signal Gout[1] through an output terminal (“Gout”). The first scan unit GOA [1] is configured to receive a second clock signal from the second clock signal line CSL2 through a first clock terminal CLK1, a third clock signal from the third clock signal line CSL3 through a second clock terminal CLK2, a fourth clock signal from the fourth clock signal line CSL4 through a third clock terminal CLK3, the first reference voltage signal from the first reference voltage terminal VGH, and the third reference voltage signal from the third reference voltage terminal VGL.

The second scan unit GOA [2] is configured to receive an output from the dummy unit GOA_dummy[1] through an input terminal (“Input”), and configured to output an output signal Gout[2] through an output terminal (“Gout”). The second scan unit GOA[2] is configured to receive a third clock signal from the third clock signal line CSL3 through a first clock terminal CLK1, a fourth clock signal from the fourth clock signal line CSL4 through a second clock terminal CLK2, a first clock signal from the first clock signal line CSL1 through a third clock terminal CLK3, the first reference voltage signal from the first reference voltage terminal VGH, and the third reference voltage signal from the third reference voltage terminal VGL.

The third scan unit GOA[3] is configured to receive an output from the first scan unit GOA[1] through an input terminal (“Input”), and configured to output an output signal Gout[3] through an output terminal (“Gout”). The third scan unit GOA[3] is configured to receive a fourth clock signal from the fourth clock signal line CSL4 through a first clock terminal CLK1, a first clock signal from the first clock signal line CSL1 through a second clock terminal CLK2, a second clock signal from the second clock signal line CSL2 through a third clock terminal CLK3, the first reference voltage signal from the first reference voltage terminal VGH, and the third reference voltage signal from the third reference voltage terminal VGL.

The n-th scan unit GOA[n] is configured to receive an output from an (n−2)-th scan unit through an input terminal (“Input”), and configured to output an output signal Gout[n] through an output terminal (“Gout”). The n-th scan unit GOA[n] is configured to receive a first clock signal from the first clock signal line CSL1 through a first clock terminal CLK1, a second clock signal from the second clock signal line CSL2 through a second clock terminal CLK2, a third clock signal from the third clock signal line CSL3 through a third clock terminal CLK3, the first reference voltage signal from the first reference voltage terminal VGH, and the third reference voltage signal from the third reference voltage terminal VGL.

In some embodiments, the scan circuit includes more than one dummy units. In one example, the scan circuit includes a dummy unit GOA_dummy[1] connected to the first scan unit GOA[1], and another dummy unit connected to the n-th scan unit. The output from the dummy unit is not provided to the subpixels. By having the dummy unit, the output of the scan circuit can be stabilized.

In some embodiments, gate electrodes of thirteenth transistors in two adjacent scan units in two adjacent stages are configured to receive a third clock signal from the third clock signal line CSL3 and a fourth clock signal from the fourth clock signal line CSL4, respectively.

In some embodiments, gate electrodes of input transistors in two adjacent scan units in two adjacent stages are configured to receive a second clock signal from the second clock signal line CSL2 and a first clock signal from the first clock signal line CSL1, respectively.

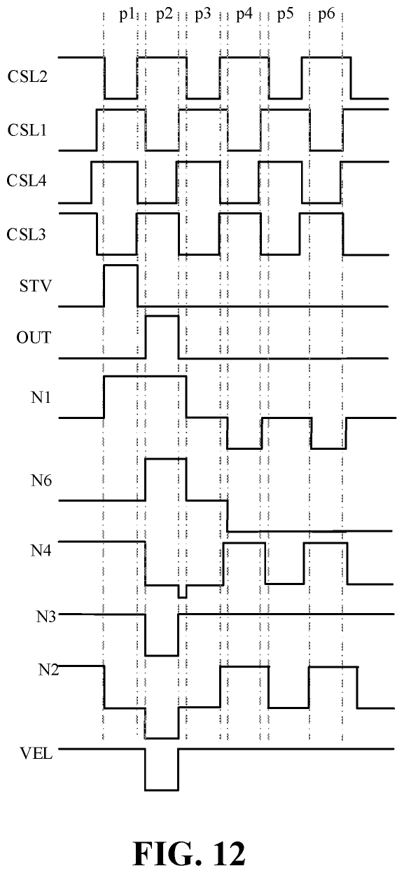

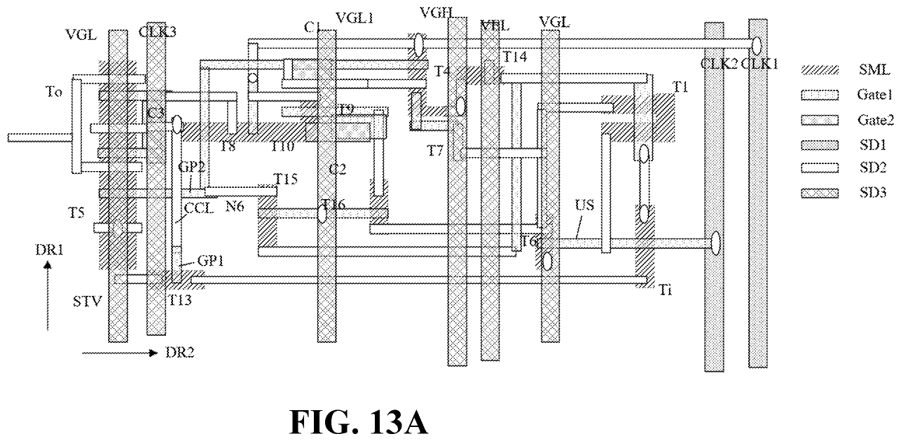

FIG. 12 is a timing diagram illustrating the operation of a respective scan unit in some embodiments according to the present disclosure. Referring to FIG. 12, the operation of the respective scan unit in some embodiments includes a first period p1, a second period p2, a third period p3, a fourth period p4, a fifth period p5, and a sixth period p6. The operation of the respective scan unit depicted in FIG. 12 is applicable to any of the embodiments described herein, for example, the respective scan unit depicted in FIG. 4, FIG. 6, FIG. 7, FIG. 8, FIG. 9, and FIG. 10. In one example, FIG. 12 depicts an operation of the respective scan unit depicted in FIG. 9.

In some embodiments, the first clock terminal CLK1, the second clock terminal CLK2, and the third clock terminal CLK3 are configured to receive three clock signals from the first clock signal line CSL1, the second clock signal line CSL2, the third clock signal line CLK3, or the fourth clock signal line CLK4. In one example, the first clock terminal CLK1 is configured to receive a first clock signal from the first clock signal line CSL1, the second clock terminal CLK2 is configured to receive a second clock signal from the second clock signal line CSL2, and the third clock terminal CLK3 is configured to receive a third clock signal from the third clock signal line CSL3. In another example, the first clock terminal CLK1 is configured to receive a second clock signal from the second clock signal line CSL2, the second clock terminal CLK2 is configured to receive a third clock signal from the third clock signal line CSL3, and the third clock terminal CLK3 is configured to receive a fourth clock signal from the fourth clock signal line CSL4. In another example, the first clock terminal CLK1 is configured to receive a third clock signal from the third clock signal line CSL3, the second clock terminal CLK2 is configured to receive a fourth clock signal from the fourth clock signal line CSL4, and the third clock terminal CLK3 is configured to receive a first clock signal from the first clock signal line CSL1. In another example, the first clock terminal CLK1 is configured to receive a fourth clock signal from the fourth clock signal line CSL4, the second clock terminal CLK2 is configured to receive a first clock signal from the first clock signal line CSL1, and the third clock terminal CLK3 is configured to receive a second clock signal from the second clock signal line CSL2.

During the first period p1 (e.g., an input period), the second clock signal line CSL2 and the third clock signal line CSL3 are configured to provide an effective voltage (e.g., a low voltage), the first clock signal line CSL1 is configured to provide an ineffective voltage (e.g., a high voltage), and the start signal STV is an ineffective voltage (e.g., a high voltage). During the first period p1, the thirteenth transistor T13 and the input transistor Ti are turned on. When the thirteenth transistor T13 is turned on, and the potential at the first node N1 is high. When the potential at the first node N1 is high, the seventeenth transistor T17 is turned off, the first transistor T1, the eighth transistor T8, and the fourth transistor T4 are off. Optionally, when the respective scan unit includes a fifteenth transistor T15, the fifteenth transistor T15 is turned on. The sixth transistor T6 is turned on, the potential at the second node N2 is low. The ninth transistor T9 is turned on, and the potential at the third node N3 is high. The tenth transistor T10 is off, the fourth node N4 has a high potential. The seventh transistor T7 is turned on, charging the fifth node N5 to a high potential. The eleventh transistor T11 is turned off, and the potential at the sixth node N6 remains low. The eighth transistor T8 is turned on, the potential at the fourth node N4 remains high. The fifth transistor T5 is turned on, the output transistor To is turned off, and the output terminal OUT outputs a low voltage.

During the second period p2 (e.g., an output period), the second clock signal line CSL2 and the third clock signal line CSL3 are configured to provide an ineffective voltage (e.g., a high voltage). The first clock signal line CSL1 is configured to provide an effective voltage (e.g., a low voltage), and the start signal STV is an effective voltage (e.g., a low voltage). During the second period p2, the thirteenth transistor T13 and the input transistor Ti are turned off. The potential at the first node N1 remains high. The fourth transistor T4 is turned off, the seventeenth transistor T17 is turned off, and the potential at the sixth node N6 is low. The eighth transistor T8 is turned on, the ninth transistor T9 is turned on, and the potential at the second node N2 is further lowered by the second capacitor C2. The ninth transistor T9 is turned on, and the potential at the third node N3 is low. The tenth transistor T10 is turned on, the enabling control signal VEL is at a low potential, the eleventh transistor T11 is on, and the potential at the sixth node N6 becomes high; and the fourteenth transistor T14 is turned on, and the potential at the first node N1 becomes high. The eighth transistor T8 turns off, the fifth transistor T5 turns off, and the potential at the fourth node N4 becomes low. The output transistor To turns on, and the output terminal OUT outputs a high voltage.

During the third period p3 (e.g., a reset period), the second clock signal line CSL2 and the third clock signal line CSL3 are configured to provide an effective voltage (e.g., a low voltage), the first clock signal line CSL1 is configured to provide an ineffective voltage (e.g., a high voltage), and the start signal STV is an effective voltage (e.g., a low voltage). During the third period p3, the thirteenth transistor T13 and the input transistor Ti are turned on, lowering the potential at the first node N1. When the potential at the first node N1 is low, the seventeenth transistor T17 is turned on, lowering the potential at the sixth node N6. The fifth transistor T5 is turned on, resulting in a low voltage output at the output terminal OUT. The sixth transistor T6 turns on, and the potential at the second node N2 is low. The ninth transistor T9 is turned on, and the potential at the third node N3 are raised. The seventh transistor T7 turns off, and the tenth transistor T10 turns off.

During the third period p3, when the third clock signal provided by the third clock signal line CSL3 transitions from a high level to a low level before the first clock signal provided by the first clock signal line CSL transitions from a high level to a low level, the voltage at node N4 is further reduced due to the coupling effect of the third capacitor C3 (thus, in FIG. 12, there is a downward protrusion at node N4).

During the third period p3, the eighth transistor T8 turns on, and the potential at the fourth node N4 becomes low. The output transistor To also turns on, and the enabling control signal VEL is at a high potential, keeping the sixth node N6 at a low voltage. Through the simultaneous discharge by the output transistor To and the fifth transistor T5 at the output terminal OUT, the discharge speed at the output terminal OUT is improved, enabling a complete and rapid reset of the gate drive signal.

During the fourth period p4 (e.g., a first stage of a maintaining period), the second clock signal line CSL2 and the third clock signal line CSL3 are configured to provide an ineffective voltage (e.g., a high voltage). The first clock signal line CSL1 is configured to provide an effective voltage (e.g., a low voltage), and the start signal STV is an effective voltage (e.g., a low voltage). During the fourth period p4, the thirteenth transistor T13 and the input transistor Ti are turned off. The potential at the first node N1 remains low. The seventeenth transistor T17 is turned on, maintaining the potential at the sixth node N6 low. The fifth transistor T5 is turned on, ensuring that the output terminal OUT outputs a low voltage level signal from the third reference voltage terminal VGL, unaffected by noise interference. The sixth transistor T6 is turned off, and the first transistor T1 is turned on, resulting in high potentials at the second node N2 and the third node N3. The tenth transistor T10 and the eighth transistor T8 are turned on, causing the fourth node N4 to have a high potential, while the fourth transistor T4 is turned off, and the TO is off. The enabling control signal VEL is at a high potential, and the sixth node N6 remains at a low potential, ensuring that the output terminal OUT outputs a low voltage level signal from the third reference voltage terminal VGL.

During the fourth period p4, the first clock signal provided by the first clock signal line CSL1 is at a low level, and due to the coupling effect of the first capacitor C1, the voltage at the first node N1 is pulled down, further lowering the level and also reducing the voltage at the sixth node N6.

During the fifth period p5 (e.g., a second stage of a maintaining period), the second clock signal line CSL2 and the third clock signal line CSL3 are configured to provide an effective voltage (e.g., a low voltage), the first clock signal line CSL1 is configured to provide an ineffective voltage (e.g., a high voltage), and the start signal STV is an effective voltage (e.g., a low voltage). During the fifth period p5, the thirteenth transistor T13 and the input transistor Ti are turned on, keeping the potential at the first node N1 low. The seventeenth transistor T17 is turned on, which in turn turning on the fifth transistor T5, ensuring that the output terminal OUT outputs a low voltage level signal from the third reference voltage terminal VGL, unaffected by noise interference. The sixth transistor T6 is turned on, and the potential at the second node N2 is low. The ninth transistor T9 turned on, the tenth transistor T10 is turned off, the eighth transistor T8 is turned on, and the potential at the fourth node N4 becomes high. The transistor TO is turned off, and the output terminal OUT outputs a low voltage level signal from the third reference voltage terminal VGL.

During the fifth period p5, the first clock signal provided by the first clock signal line CSL1 is at a high level. Due to the coupling effect of the first capacitor C1, the voltage at the first node N1 is pulled up to some extent, while the sixth node N6 remains at the corresponding low level due to the effect of the fourth capacitor C4.

During the sixth period p6 (e.g., a third stage of a maintaining period), the second clock signal line CSL2 and the third clock signal line CSL3 are configured to provide an ineffective voltage (e.g., a high voltage). The first clock signal line CSL1 is configured to provide an effective voltage (e.g., a low voltage), and the start signal STV is an effective voltage (e.g., a low voltage). During the sixth period p6, the thirteenth transistor T13 and the input transistor Ti are turned off. The potential at the first node N1 remains low. The seventeenth transistor T17 is turned on, maintaining the potential at the sixth node N6 low. The fifth transistor T5 is turned on, ensuring that the output terminal OUT outputs a low voltage level signal from the third reference voltage terminal VGL, unaffected by noise interference. The sixth transistor T6 is turned off, and the first transistor T1 is turned on, resulting in high potentials at the second node N2 and the third node N3. The tenth transistor T10 and the eighth transistor T8 are turned on, causing the fourth node N4 to have a high potential, while the fourth transistor T4 is turned off. The transistor TO is turned off, The enabling control signal VEL is at a high potential, and the sixth node N6 remains at a low potential, ensuring that the output terminal OUT outputs a low voltage level signal from the third reference voltage terminal VGL.

FIG. 11B is a schematic diagram of a scan circuit in some embodiments according to the present disclosure. Referring to FIG. 11B, the scan circuit in some embodiments includes a plurality of stages, a respective stage of the plurality of stages comprising a respective scan unit of a plurality of scan units. The scan circuit in some embodiments is configured to provide control signals to rows of subpixels in a display panel. Examples of control signals include gate scanning signals, reset control signals, and light emitting control signals. In one example, the scan circuit is a gate scanning signal scan circuit configured to provide gate scanning signals to the plurality of gate lines. In another example, the scan circuit is a light emitting control signal scan circuit configured to provide light emitting control signals to the plurality of light emitting control signal lines. In another example, the scan circuit is a reset control signal scan circuit configured to provide reset control signals to the plurality of reset control signal lines.

Referring to FIG. 11B, in some embodiments, the scan circuit includes n number of scan units cascaded. The n number of scan units include a first scan unit GOA[1], a second scan unit GOA[2], . . . , a (n−1)-th scan unit GOA[n−1], and a n-th scan unit GOA[n]. Optionally, the scan circuit further includes a dummy unit GOA_dummy[1].

The scan circuit is configured to receive clock signals from a first clock signal line CSL1, a second clock signal line CSL2, a third clock signal line CSL3, and a fourth clock signal line CSL4, configured to receive a first reference voltage signal from a first reference voltage terminal VGH, and configured to receive a third reference voltage signal from a third reference voltage terminal VGL.

The dummy unit GOA_dummy[1] is configured to receive a start signal STV through an input terminal (“Input”), and configured to output an output signal Gout_dummy through an output terminal (“Gout”). The dummy unit GOA_dummy[1] is configured to receive a first clock signal from the first clock signal line CSL1 through a first clock terminal CLK1, a second clock signal from the second clock signal line CSL2 through a second clock terminal CLK2, a third clock signal from the third clock signal line CSL3 through a third clock terminal CLK3, the first reference voltage signal from the first reference voltage terminal VGH, and the third reference voltage signal from the third reference voltage terminal VGL.

The first scan unit GOA[1] is configured to receive an output from the dummy unit GOA_dummy[1] through an input terminal (“Input”), and configured to output an output signal Gout[1] through an output terminal (“Gout”). The first scan unit GOA[1] is configured to receive a second clock signal from the second clock signal line CSL2 through a first clock terminal CLK1, a first clock signal from the first clock signal line CSL1 through a second clock terminal CLK2, a fourth clock signal from the fourth clock signal line CSL4 through a third clock terminal CLK3, the first reference voltage signal from the first reference voltage terminal VGH, and the third reference voltage signal from the third reference voltage terminal VGL.

The second scan unit GOA[2] is configured to receive an output from the first scan unit GOA[1] through an input terminal (“Input”), and configured to output an output signal Gout[2] through an output terminal (“Gout”). The second scan unit GOA[2] is configured to receive a first clock signal from the first clock signal line CSL1 through a first clock terminal CLK1, a second clock signal from the second clock signal line CSL2 through a second clock terminal CLK2, a third clock signal from the third clock signal line CSL3 through a third clock terminal CLK3, the first reference voltage signal from the first reference voltage terminal VGH, and the third reference voltage signal from the third reference voltage terminal VGL.

The (n−1)-th scan unit GOA[n−1] is configured to receive an output from the dummy unit GOA[n−2] through an input terminal (“Input”), and configured to output an output signal Gout[n−1] through an output terminal (“Gout”). The (n−1)-th scan unit GOA[n−1] is configured to receive a second clock signal from the second clock signal line CSL2 through a first clock terminal CLK1, a first clock signal from the first clock signal line CSL1 through a second clock terminal CLK2, a fourth clock signal from the fourth clock signal line CSL4 through a third clock terminal CLK3, the first reference voltage signal from the first reference voltage terminal VGH, and the third reference voltage signal from the third reference voltage terminal VGL.

The n-th scan unit GOA[n] is configured to receive an output from the first scan unit GOA[n−1] through an input terminal (“Input”), and configured to output an output signal Gout[n] through an output terminal (“Gout”). The n-th scan unit GOA[n] is configured to receive a first clock signal from the first clock signal line CSL1 through a first clock terminal CLK1, a second clock signal from the second clock signal line CSL2 through a second clock terminal CLK2, a third clock signal from the third clock signal line CSL3 through a third clock terminal CLK3, the first reference voltage signal from the first reference voltage terminal VGH, and the third reference voltage signal from the third reference voltage terminal VGL.

In some embodiments, first clock terminals of two adjacent scan units are configured to receive two different clock signals from the first clock signal line CSL1 and the second clock signal line CSL2, respectively. In some embodiments, second clock terminals of two adjacent scan units are configured to receive two different clock signals from the first clock signal line CSL1 and the second clock signal line CSL2, respectively. In some embodiments, a first clock terminal and a second clock terminal in the respective scan unit are configured to receive two different clock signals from the first clock signal line CSL1 and the second clock signal line CSL2, respectively.

In some embodiments, third clock terminals of two adjacent scan units are configured to receive two different clock signals from the third clock signal line CSL3 and the fourth clock signal line CSL4, respectively.

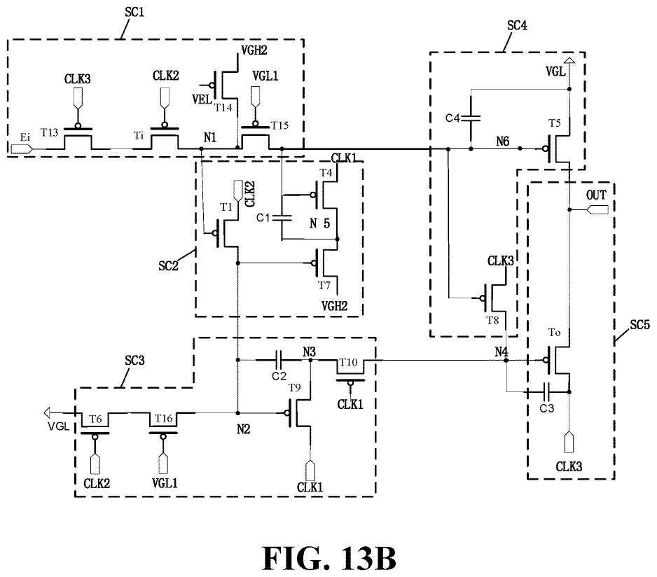

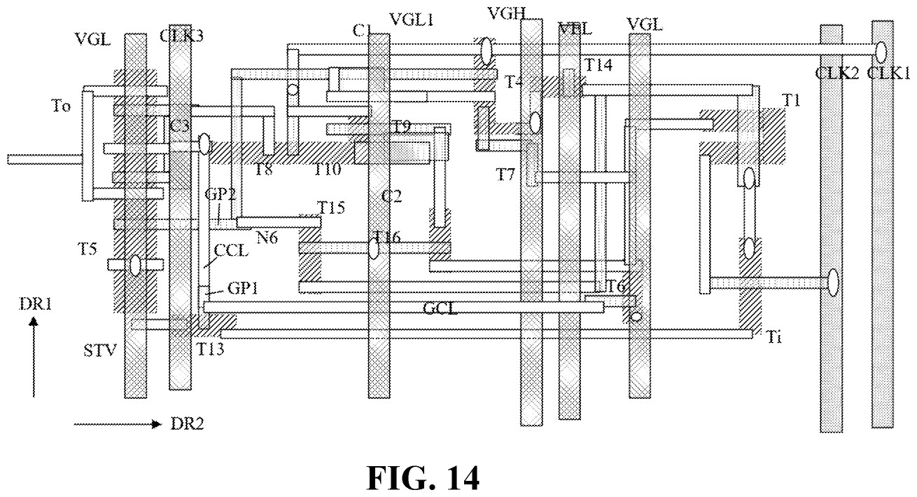

FIG. 13A is a schematic diagram illustrating the structure of various layers of a respective scan unit in some embodiments according to the present disclosure. FIG. 13B is a circuit diagram of a respective scan unit in some embodiments according to the present disclosure. Referring to FIG. 13A and FIG. 13B, the respective scan unit in some embodiments includes a first subcircuit SC1, a second subcircuit SC2, a third subcircuit SC3, a fourth subcircuit SC4, and a fifth subcircuit SC5.

In some embodiments, the first subcircuit SC1 is configured to receive an input signal from an input terminal Ei. The input terminal Ei is configured to receive a start signal or an output signal from an output terminal of a previous scan unit (e.g., a (n−1)-th scan unit SU(n−1), a (n−2)-th scan unit, or a (n−3)-th scan unit). As used herein, the term “previous scan unit” is not limited to immediately previous scan unit (e.g., the (n−1)-th scan unit), but includes any appropriate previous scan unit (e.g., the (n−2)-th scan unit, or the (n−3)-th scan unit). In some embodiments, the first subcircuit SC1 is connected to a first node N1.

In some embodiments, the second subcircuit SC2 is connected to the first node N1, connected to a second node N2.

In some embodiments, the third subcircuit SC3 is connected to the second node N2, and connected to a third node N3.

In some embodiments, the fourth subcircuit SC4 is connected to a fourth node N4, and connected to a sixth node N6.

In some embodiments, the fifth subcircuit SC5 is configured to output an output signal through an output terminal OUT. In some embodiments, the fifth subcircuit SC5 is connected to the fourth node N4.

In some embodiments, the first subcircuit SC1 includes an input transistor T1, a thirteenth transistor T13, a fourteenth transistor T14, and a fifteenth transistor T15.

A gate electrode of the thirteenth transistor T13 is configured to receive a third clock signal from a third clock terminal CLK3. A first electrode of the thirteenth transistor T13 is configured to receive an input signal from an input terminal Ei. A second electrode of the thirteenth transistor T13 is connected to a first electrode of the input transistor T1.

A gate electrode of the input transistor T1 is configured to receive a second clock signal from a second clock terminal CLK2. A first electrode of the input transistor T1 is connected to a second electrode of the thirteenth transistor T13. A second electrode of the input transistor T1 is connected to a first node N1.

A gate electrode of the fourteenth transistor T14 is configured to receive an enabling control signal VEL. A first electrode of the fourteenth transistor T14 is configured to receive a second reference voltage signal from a second reference voltage terminal VGH2. A second electrode of the fourteenth transistor T14 is connected to the first node N1.

A gate electrode of the fifteenth transistor T15 is configured to receive a fourth reference voltage signal from a fourth reference voltage terminal VGL1. A first electrode of the fifteenth transistor T15 is connected to the first node N1. A second electrode of the fifteenth transistor T15 is connected to the sixth node N6.

In some embodiments, the second subcircuit SC2 includes a first transistor T1, a fourth transistor T4, a seventh transistor T7, and a first capacitor C1. A gate electrode of the first transistor T1 is connected to the first node N1. A first electrode of the first transistor T1 is configured to receive the second clock signal from the second clock terminal CLK2. A second electrode of the first transistor T1 is connected to a second node N2.

A gate electrode of the fourth transistor T4 is connected to the sixth node N6. A first electrode of the fourth transistor T4 is configured to receive a first clock signal from a first clock terminal CLK1. A second electrode of the fourth transistor T4 is connected to a fifth node N5.

A gate electrode of the seventh transistor T7 is connected to the second node N2. A first electrode of the seventh transistor T7 is configured to receive the second reference voltage signal from the second reference voltage terminal VGH2. A second electrode of the seventh transistor T7 is connected to the fifth node N5.

A first electrode of the first capacitor C1 is connected to the sixth node N6. A second electrode of the first capacitor C1 is connected to the fifth node N5.

In some embodiments, the third subcircuit SC3 includes a sixth transistor T6, a ninth transistor T9, a tenth transistor T10, a sixteenth transistor T16, and a second capacitor C2.

A gate electrode of the sixth transistor T6 is configured to receive the second clock signal from the second clock terminal CLK2. A first electrode of the sixth transistor T6 is configured to receive a third reference voltage signal from a third reference voltage terminal VGL. A second electrode of the sixth transistor T6 is connected to a first electrode of the sixteenth transistor T16.

In the respective scan unit depicted in FIG. 4, the first electrode of the sixth transistor T6 is configured to receive a third reference voltage signal from a third reference voltage terminal VGL, e.g., a low level voltage signal for an extended period, which may cause the threshold voltage of the sixth transistor to shift. The inventors of the present disclosure discover that, by having a sixteenth transistor T16, the effect of low level signal on the sixth transistor T6 can be mitigated.

A gate electrode of the sixteenth transistor T16 is configured to receive the fourth reference voltage signal from the fourth reference voltage terminal VGL1. A first electrode of the sixteenth transistor T16 is connected to the second electrode of the sixth transistor T6. A second electrode of the sixteenth transistor T16 is connected to the second node N2. The sixteenth transistor T16 is configured to be turned on as long as the gate electrode of the sixteenth transistor T16 receives the fourth reference voltage signal (e.g., a low level voltage signal).

A gate electrode of the ninth transistor T9 is connected to the second node N2. A first electrode of the ninth transistor T9 is configured to receive the first clock signal from the first clock terminal CLK1. A second electrode of the ninth transistor T9 is connected to a third node N3.

A gate electrode of the tenth transistor T10 is configured to receive the first clock signal from the first clock terminal CLK1. A first electrode of the tenth transistor T10 is connected to the third node N3. A second electrode of the tenth transistor T10 is connected to a fourth node N4.

A first electrode of the second capacitor C2 is connected to the second node N2. A second electrode of the second capacitor C2 is connected to the third node N3.

In some embodiments, the fourth subcircuit SC4 includes a fifth transistor T5, an eighth transistor T8, and a fourth capacitor C4. A gate electrode of the fifth transistor T5 is connected to a sixth node N6. A first electrode of the fifth transistor T5 is configured to receive the third reference voltage signal from the third reference voltage terminal VGL. A second electrode of the fifth transistor T5 is connected to an output terminal OUT.

A gate electrode of the eighth transistor T8 is connected to a sixth node N6. A first electrode of the eighth transistor T8 is configured to receive the third clock signal from the third clock terminal CLK3. A second electrode of the eighth transistor T8 is connected to the fourth node N4.

In some embodiments, the first reference voltage signal, the second reference voltage signal, the third reference voltage signal, and the fourth reference voltage signal are different from each other. In some embodiments, the first reference voltage signal, the second reference voltage signal, the third reference voltage signal, and the fourth reference voltage signal are constant voltage signals. In some embodiments, the first reference voltage signal has a voltage level higher than a voltage level of the third reference voltage signal. In some embodiments, the second reference voltage signal has a voltage level higher than a voltage level of the third reference voltage signal. In some embodiments, the first reference voltage signal has a voltage level higher than a voltage level of the fourth reference voltage signal. In some embodiments, the second reference voltage signal has a voltage level higher than a voltage level of the fourth reference voltage signal.

A first electrode of the fourth capacitor C4 is configured to receive the third reference voltage signal from the third reference voltage terminal VGL. A second electrode of the fourth capacitor C4 is connected to the sixth node N6.

In some embodiments, the fifth subcircuit SC5 includes an output transistor To and a third capacitor C3. A gate electrode of the output transistor To is connected to the fourth node N4. A first electrode of the output transistor To is configured to receive the third clock signal from the third clock terminal CLK3 (alternatively, the first reference voltage signal from the first reference voltage terminal VGH). A second electrode of the output transistor To is connected to the output terminal OUT.

A first electrode of the third capacitor C3 is connected to the fourth node N4. A second electrode of the third capacitor C3 is configured to receive the third clock signal from the third clock terminal CLK3 (alternatively, the first reference voltage signal from the first reference voltage terminal VGH).

The inventors of the present disclosure discover that, by having the thirteenth transistor T13, the fourteenth transistor T14, and the fifteenth transistor T15 in the first subcircuit, the effect of low level signal on the input transistor Ti can be mitigated. The thirteenth transistor T13 is placed in front of the input transistor Ti, where the gate electrode of the input transistor T1 is connected to the second clock terminal CLK2, and the gate electrode of the thirteenth transistor T13 is connected to the third clock terminal CLK3. The main function of the thirteenth transistor T13 is to isolate the effect of the low level signal on the input transistor T1.

Referring to FIG. 13A and FIG. 13B, the respective scan unit in some embodiments includes a semiconductor material layer SML comprising active layers of transistors in the respective scan unit, a first gate metal layer Gate1 on a side of the semiconductor material layer SML away from a base substrate, a second gate metal layer Gate2 on a side of the first gate metal layer Gate1 away from the base substrate, a first signal line layer SD1 on a side of the second gate metal layer Gate2 away from the base substrate, a second signal line layer SD2 on a side of the first signal line layer SD1 away from the base substrate, and a third signal line layer SD3 on a side of the second signal line layer SD2 away from the base substrate.

In some embodiments, the respective scan unit includes a first clock terminal CLK1, a second clock terminal CLK2, and a third clock terminal CLK3. The first clock terminal CLK1, the second clock terminal CLK2, and the third clock terminal CLK3 are connected to three of a first clock signal line, a second clock signal line, a third clock signal line, and a fourth clock signal line. Optionally, the first clock terminal CLK1, the second clock terminal CLK2 are in the first signal line layer SD1. Optionally, the third clock terminal CLK3 is in the third signal line layer SD3.

In some embodiments, an orthographic projection of the third clock terminal CLK3 on a base substrate spaces apart an orthographic projection the output transistor To and the fifth transistor T5 on the base substrate from an orthographic projection of capacitors and transistors other than the output transistor To and the fifth transistor T5 on the base substrate. In some embodiments, an orthographic projection of the third clock terminal CLK3 on a base substrate spaces apart an orthographic projection the third reference voltage terminal VGL on the base substrate and an orthographic projection the fourth reference voltage terminal VGL1 on the base substrate. In some embodiments, along the second direction DR2, the third reference voltage terminal VGL, the third clock terminal CLK3, the fourth reference voltage terminal VGL1, the first reference voltage terminal VGH are sequentially arranged.

In some embodiments, the orthographic projection of capacitors and transistors other than the output transistor To and the fifth transistor T5 on the base substrate is between the orthographic projection of the third clock terminal CLK3 on the base substrate and an orthographic projection of the second clock terminal CLK2 on the base substrate.

In some embodiments, a gate electrode of the sixth transistor T6 is connected to the second clock terminal CLK2. Optionally, gate electrodes of the sixth transistor T6 and the input transistor Ti are parts of a unitary structure US.

FIG. 14 is a schematic diagram illustrating the structure of various layers of a respective scan unit in some embodiments according to the present disclosure. In one example, the respective scan unit depicted in FIG. 14 corresponds to the respective scan unit depicted in FIG. 7. Referring to FIG. 14, in some embodiments, the respective scan unit in some embodiments includes a semiconductor material layer SML comprising active layers of transistors in the respective scan unit, a first gate metal layer Gate1 on a side of the semiconductor material layer SML away from a base substrate, a second gate metal layer Gate2 on a side of the first gate metal layer Gate1 away from the base substrate, a first signal line layer SD1 on a side of the second gate metal layer Gate2 away from the base substrate, a second signal line layer SD2 on a side of the first signal line layer SD1 away from the base substrate, and a third signal line layer SD3 on a side of the second signal line layer SD2 away from the base substrate.

In some embodiments, the respective scan unit includes a first clock terminal CLK1, a second clock terminal CLK2, and a third clock terminal CLK3. The first clock terminal CLK1, the second clock terminal CLK2, and the third clock terminal CLK3 are connected to three of a first clock signal line, a second clock signal line, a third clock signal line, and a fourth clock signal line. Optionally, the first clock terminal CLK1, the second clock terminal CLK2 are in the first signal line layer SD1. Optionally, the third clock terminal CLK3 is in the third signal line layer SD3.

In some embodiments, an orthographic projection of the third clock terminal CLK3 on a base substrate spaces apart an orthographic projection the output transistor To and the fifth transistor T5 on the base substrate from an orthographic projection of capacitors and transistors other than the output transistor To and the fifth transistor T5 on the base substrate.

In some embodiments, the orthographic projection of capacitors and transistors other than the output transistor To and the fifth transistor T5 on the base substrate is between the orthographic projection of the third clock terminal CLK3 on the base substrate and an orthographic projection of the second clock terminal CLK2 on the base substrate.

In some embodiments, a gate electrode of the sixth transistor T6 is connected to the third clock terminal CLK3. Optionally, gate electrodes of the sixth transistor T6 and the thirteenth transistor T13 are connected to each other through a gate connecting line GCL. Optionally, the gate connecting line GCL is in the second signal line layer SD2.

In some embodiments, an orthographic projection of the gate connecting line GCL on the base substrate at least partially overlaps with an orthographic projection of at least one of a first reference voltage terminal or a fourth reference voltage terminal on the base substrate.

In some embodiments, an orthographic projection of the first capacitor C1 on a base substrate and an orthographic projection of the second capacitor C2 on the base substrate are on a same side with respect to an orthographic projection of the gate connecting line GCL on the base substrate. In some embodiments, an orthographic projection of the third capacitor C3 on a base substrate at least partially overlaps with an orthographic projection of the third clock terminal CLK3 on the base substrate. In some embodiments, an orthographic projection of the first capacitor C1 on a base substrate and an orthographic projection of the second capacitor C2 on the base substrate are on a side of an orthographic projection of the third capacitor C3 on a base substrate away from an orthographic projection of the output transistor To on the base substrate. In some embodiments, a shortest distance between an orthographic projection of the first capacitor C1 on a base substrate and an orthographic projection of the second capacitor C2 on the base substrate is less than a width of the respective scan unit along the first direction DR1.

In FIG. 13A, and FIG. 14 to FIG. 19, white circles and elliptical circles denote vias.

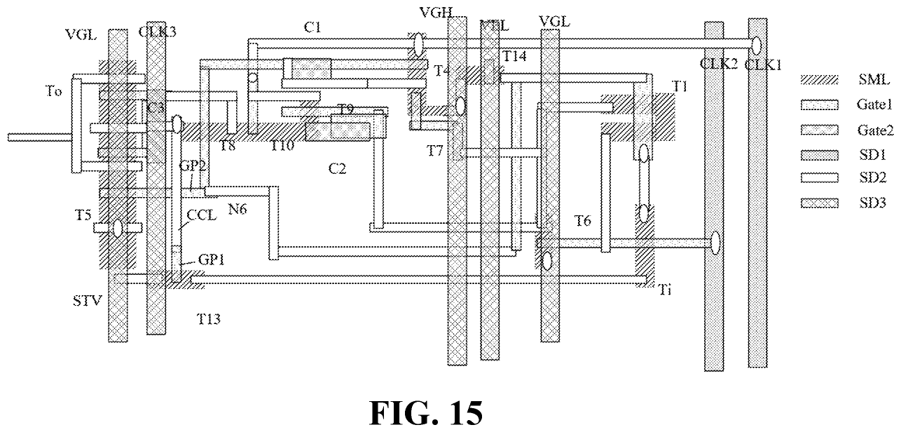

FIG. 15 is a schematic diagram illustrating the structure of various layers of a respective scan unit in some embodiments according to the present disclosure. Compared to the respective scan unit depicted in FIG. 13A, the respective scan unit depicted in FIG. 15 does not have the fifteenth transistor T15 or the sixteenth transistor T16.

Referring to FIG. 13A to FIG. 15, the respective scan unit in some embodiments includes a first gate pad GP1 comprising a gate electrode of the thirteenth transistor T13, a second gate pad GP2 comprising a gate electrode of the fifth transistor T5, and a clock connecting line CCL connecting the first gate pad GP1 to the third clock terminal CLK3 and to a first electrode of the eighth transistor T8. Optionally, the clock connecting line CCL is in the second signal line layer SD2. Optionally, the first gate pad GP1 and the second gate pad GP2 are in the first gate metal layer Gate1. Optionally, the third clock terminal CLK3 is in the third signal line layer SD3.

In some embodiments, an orthographic projection of the clock connecting line CCL on a base substrate partially overlaps with an orthographic projection of the second gate pad GP2 on the base substrate. The inventors of the present disclosure discover that this overlap can easily cause coupling of the gate electrode of the fifth transistor T5, when the third clock terminal CLK3 is configured to provide a low level signal, leading to voltage fluctuations at the gate electrode of the fifth transistor T5, which may result in incorrect output (especially when the third clock terminal CLK3 turns on slightly earlier than the second clock terminal CLK2). In particular, when the eighth transistor T8, the output transistor To, and the thirteenth transistor T13 are connected to the third clock terminal CLK3 through a unitary connection line, this coupling with the fifth transistor T5 can potentially cause voltage fluctuations in multiple transistors.

In the respective scan unit depicted in FIG. 13A to FIG. 15, the clock connecting line CCL is in the second signal line layer SD2, and the second gate pad GP2 is in the first gate metal layer Gate1. A shortest distance between the thirteenth transistor T13 and the output transistor To is greater than a shortest distance between the thirteenth transistor T13 and the fifth transistor T5.

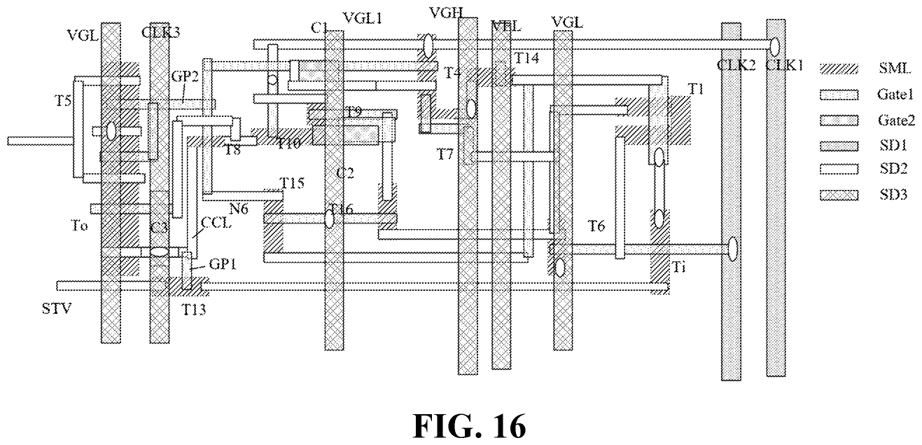

FIG. 16 is a schematic diagram illustrating the structure of various layers of a respective scan unit in some embodiments according to the present disclosure. Referring to FIG. 16, the respective scan unit in some embodiments includes a semiconductor material layer SML comprising active layers of transistors in the respective scan unit, a first gate metal layer Gate1 on a side of the semiconductor material layer SML away from a base substrate, a second gate metal layer Gate2 on a side of the first gate metal layer Gate1 away from the base substrate, a first signal line layer SD1 on a side of the second gate metal layer Gate2 away from the base substrate, a second signal line layer SD2 on a side of the first signal line layer SD1 away from the base substrate, and a third signal line layer SD3 on a side of the second signal line layer SD2 away from the base substrate.

In some embodiments, the respective scan unit includes a first clock terminal CLK1, a second clock terminal CLK2, and a third clock terminal CLK3. The first clock terminal CLK1, the second clock terminal CLK2, and the third clock terminal CLK3 are connected to three of a first clock signal line, a second clock signal line, a third clock signal line, and a fourth clock signal line. Optionally, the first clock terminal CLK1, the second clock terminal CLK2 are in the first signal line layer SD1. Optionally, the third clock terminal CLK3 is in the third signal line layer SD3.

In some embodiments, an orthographic projection of the third clock terminal CLK3 on a base substrate spaces apart an orthographic projection the output transistor To and the fifth transistor T5 on the base substrate from an orthographic projection of capacitors and transistors other than the output transistor To and the fifth transistor T5 on the base substrate.

In some embodiments, the orthographic projection of capacitors and transistors other than the output transistor To and the fifth transistor T5 on the base substrate is between the orthographic projection of the third clock terminal CLK3 on the base substrate and an orthographic projection of the second clock terminal CLK2 on the base substrate.

In some embodiments, a gate electrode of the sixth transistor T6 is connected to the second clock terminal CLK2. Optionally, gate electrodes of the sixth transistor T6 and the input transistor Ti are parts of a unitary structure US.

In the respective scan unit depicted in FIG. 16, a shortest distance between the thirteenth transistor T13 and the fifth transistor T5 is greater than a shortest distance between the thirteenth transistor T13 and the output transistor To.

In some embodiments, in the respective scan unit depicted in FIG. 16, a shortest distance between the thirteenth transistor T13 and the third capacitor C3 is less than a shortest distance between the thirteenth transistor T13 and the fifth transistor T5. As a comparison, in the respective scan unit depicted in FIG. 15, a shortest distance between the thirteenth transistor T13 and the third capacitor C3 is greater than a shortest distance between the thirteenth transistor T13 and the fifth transistor T5.

In some embodiments, in the respective scan unit depicted in FIG. 16, an orthographic projection of the first capacitor C1 on a base substrate and an orthographic projection of the second capacitor C2 on the base substrate are on a side of an orthographic projection of the sixth node N6 on the base substrate away from an orthographic projection of the third capacitor C3 on a base substrate. As a comparison, in the respective scan unit depicted in FIG. 15, an orthographic projection of the first capacitor C1 on a base substrate, an orthographic projection of the second capacitor C2 on the base substrate, and an orthographic projection of the third capacitor C3 on a base substrate are on a same side of an orthographic projection of the sixth node N6 on the base substrate.

In some embodiments, the respective scan unit includes a first gate pad GP1 comprising a gate electrode of the thirteenth transistor T13, a second gate pad GP2 comprising a gate electrode of the fifth transistor T5, and a clock connecting line CCL connecting the first gate pad GP1 to a first electrode of the eighth transistor T8. Optionally, the clock connecting line CCL is in the second signal line layer SD2. Optionally, the first gate pad GP1 and the second gate pad GP2 are in the first gate metal layer Gate1. Optionally, the third clock terminal CLK3 is in the third signal line layer SD3.

In some embodiments, an orthographic projection of the clock connecting line CCL on a base substrate is non-overlapping with an orthographic projection of the second gate pad GP2 on the base substrate. The inventors of the present disclosure discover that, by having the orthographic projection of the clock connecting line CCL on the base substrate non-overlapping with the orthographic projection of the second gate pad GP2 on the base substrate, voltage fluctuations at the gate electrode of the fifth transistor T5 can be obviated. In some embodiments, the clock connecting line CCL is connected to the third clock terminal CLK3.

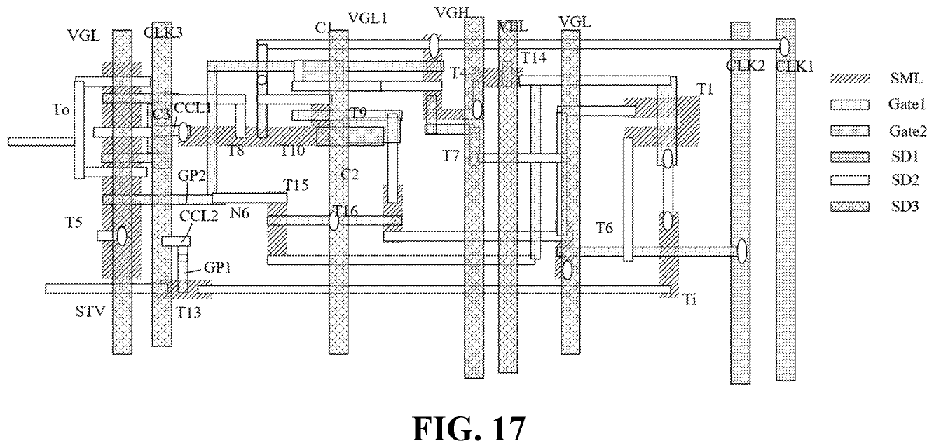

FIG. 17 is a schematic diagram illustrating the structure of various layers of a respective scan unit in some embodiments according to the present disclosure. Referring to FIG. 17, the respective scan unit in some embodiments includes a semiconductor material layer SML comprising active layers of transistors in the respective scan unit, a first gate metal layer Gate1 on a side of the semiconductor material layer SML away from a base substrate, a second gate metal layer Gate2 on a side of the first gate metal layer Gate1 away from the base substrate, a first signal line layer SD1 on a side of the second gate metal layer Gate2 away from the base substrate, a second signal line layer SD2 on a side of the first signal line layer SD1 away from the base substrate, and a third signal line layer SD3 on a side of the second signal line layer SD2 away from the base substrate.

In some embodiments, the respective scan unit includes a first clock terminal CLK1, a second clock terminal CLK2, and a third clock terminal CLK3. The first clock terminal CLK1, the second clock terminal CLK2, and the third clock terminal CLK3 are connected to three of a first clock signal line, a second clock signal line, a third clock signal line, and a fourth clock signal line. Optionally, the first clock terminal CLK1, the second clock terminal CLK2 are in the first signal line layer SD1. Optionally, the third clock terminal CLK3 is in the third signal line layer SD3.

In some embodiments, an orthographic projection of the third clock terminal CLK3 on a base substrate spaces apart an orthographic projection the output transistor To and the fifth transistor T5 on the base substrate from an orthographic projection of capacitors and transistors other than the output transistor To and the fifth transistor T5 on the base substrate.

In some embodiments, the orthographic projection of capacitors and transistors other than the output transistor To and the fifth transistor T5 on the base substrate is between the orthographic projection of the third clock terminal CLK3 on the base substrate and an orthographic projection of the second clock terminal CLK2 on the base substrate.

In some embodiments, a gate electrode of the sixth transistor T6 is connected to the second clock terminal CLK2. Optionally, gate electrodes of the sixth transistor T6 and the input transistor Ti are parts of a unitary structure US.

In some embodiments, the respective scan unit in some embodiments includes a first gate pad GP1 comprising a gate electrode of the thirteenth transistor T13, a first clock connecting line CCL1 connecting a first electrode of the eighth transistor T8 to the third clock terminal CLK3, and a second clock connecting line CCL2 connecting the first gate pad GP1 to the third clock terminal CLK3. Optionally, the first clock connecting line CCL1 and the second clock connecting line CCL2 are in the second signal line layer SD2. Optionally, the first gate pad GP1 is in the first gate metal layer Gate1. Optionally, the third clock terminal CLK3 is in the third signal line layer SD3. In some embodiments, the respective scan unit in some embodiments includes a second gate pad GP2 comprising a gate electrode of the fifth transistor T5.

In some embodiments, an orthographic projection of the first clock connecting line CCL1 on a base substrate is non-overlapping with an orthographic projection of the second gate pad GP2 on the base substrate. In some embodiments, an orthographic projection of the second clock connecting line CCL2 on the base substrate is non-overlapping with the orthographic projection of the second gate pad GP2 on the base substrate. In some embodiments, the orthographic projection of the second gate pad GP2 on the base substrate spaces apart the orthographic projection of the first clock connecting line CCL1 on the base substrate from the orthographic projection of the second clock connecting line CCL2 on the base substrate. The inventors of the present disclosure discover that, by having the orthographic projection of the first clock connecting line CCL1 on the base substrate non-overlapping with the orthographic projection of the second gate pad GP2 on the base substrate, and the orthographic projection of the second clock connecting line CCL2 on the base substrate non-overlapping with the orthographic projection of the second gate pad GP2 on the base substrate, voltage fluctuations at the gate electrode of the fifth transistor T5 can be obviated.

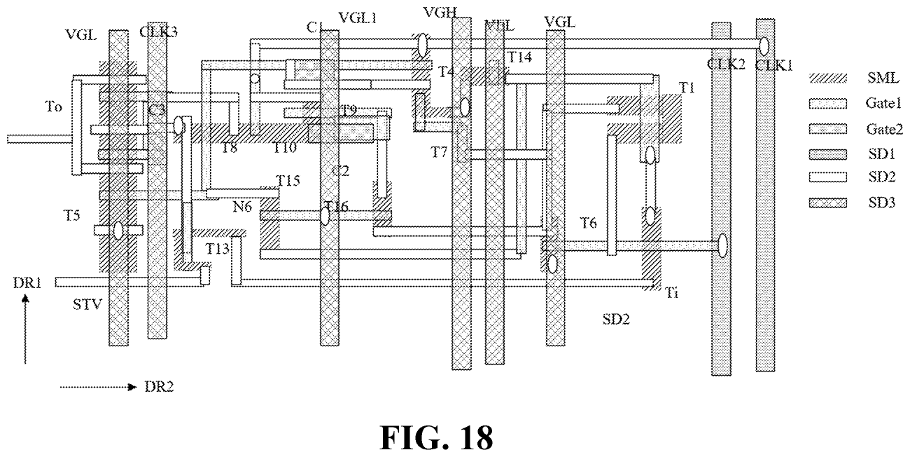

FIG. 18 is a schematic diagram illustrating the structure of various layers of a respective scan unit in some embodiments according to the present disclosure. Referring to FIG. 18, the respective scan unit in some embodiments includes a semiconductor material layer SML comprising active layers of transistors in the respective scan unit, a first gate metal layer Gate1 on a side of the semiconductor material layer SML away from a base substrate, a second gate metal layer Gate2 on a side of the first gate metal layer Gate1 away from the base substrate, a first signal line layer SD1 on a side of the second gate metal layer Gate2 away from the base substrate, a second signal line layer SD2 on a side of the first signal line layer SD1 away from the base substrate, and a third signal line layer SD3 on a side of the second signal line layer SD2 away from the base substrate.

In some embodiments, the respective scan unit includes a first clock terminal CLK1, a second clock terminal CLK2, and a third clock terminal CLK3. The first clock terminal CLK1, the second clock terminal CLK2, and the third clock terminal CLK3 are connected to three of a first clock signal line, a second clock signal line, a third clock signal line, and a fourth clock signal line. Optionally, the first clock terminal CLK1, the second clock terminal CLK2 are in the first signal line layer SD1. Optionally, the third clock terminal CLK3 is in the third signal line layer SD3.

In some embodiments, an orthographic projection of the third clock terminal CLK3 on a base substrate spaces apart an orthographic projection the output transistor To and the fifth transistor T5 on the base substrate from an orthographic projection of capacitors and transistors other than the output transistor To and the fifth transistor T5 on the base substrate.

In some embodiments, the orthographic projection of capacitors and transistors other than the output transistor To and the fifth transistor T5 on the base substrate is between the orthographic projection of the third clock terminal CLK3 on the base substrate and an orthographic projection of the second clock terminal CLK2 on the base substrate.

In some embodiments, a gate electrode of the sixth transistor T6 is connected to the second clock terminal CLK2. Optionally, gate electrodes of the sixth transistor T6 and the input transistor Ti are parts of a unitary structure US.

In some embodiments, the third clock terminal CLK3 extends along a first direction DR1. In some embodiments, the third clock terminal CLK3, the second clock terminal CLK2, and the first clock terminal CLK1 are arranged along a second direction DR2.

In some embodiments, an orthographic projection, along the second direction DR2, of an active layer of the fifth transistor T5 on a plane perpendicular to the semiconductor material layer SML, the first gate metal layer Gate1, the second gate metal layer Gate2, the first signal line layer SD1, the second signal line layer SD2, and the third signal line layer SD3 covers an orthographic projection, along the second direction DR2, of an active layer of the thirteenth transistor T13 on the plane perpendicular to the semiconductor material layer SML, the first gate metal layer Gate1, the second gate metal layer Gate2, the first signal line layer SD1, the second signal line layer SD2, and the third signal line layer SD3.

In some embodiments, an orthographic projection, along the second direction DR2, of an active layer of the input transistor Ti on a plane perpendicular to the semiconductor material layer SML, the first gate metal layer Gate1, the second gate metal layer Gate2, the first signal line layer SD1, the second signal line layer SD2, and the third signal line layer SD3 covers an orthographic projection, along the second direction DR2, of an active layer of the thirteenth transistor T13 on the plane perpendicular to the semiconductor material layer SML, the first gate metal layer Gate1, the second gate metal layer Gate2, the first signal line layer SD1, the second signal line layer SD2, and the third signal line layer SD3.

As a comparison, referring to FIG. 13A, an orthographic projection, along the second direction DR2, of an active layer of the fifth transistor T5 on a plane perpendicular to the semiconductor material layer SML, the first gate metal layer Gate1, the second gate metal layer Gate2, the first signal line layer SD1, the second signal line layer SD2, and the third signal line layer SD3 is non-overlapping with an orthographic projection, along the second direction DR2, of an active layer of the thirteenth transistor T13 on the plane perpendicular to the semiconductor material layer SML, the first gate metal layer Gate1, the second gate metal layer Gate2, the first signal line layer SD1, the second signal line layer SD2, and the third signal line layer SD3.

In some embodiments, the gate electrode of the fifth transistor T5 is in the first gate metal layer Gate1, and the third clock terminal CLK3 is in the third signal line layer SD3, reducing the parasitic capacitance between the gate electrode of the fifth transistor T5 and the third clock terminal CLK3.

The inventors of the present disclosure discover that the respective scan unit depicted in FIG. 18 has a more compact structure, leading to a narrower bezel in a display panel having the scan circuit according to the present disclosure.

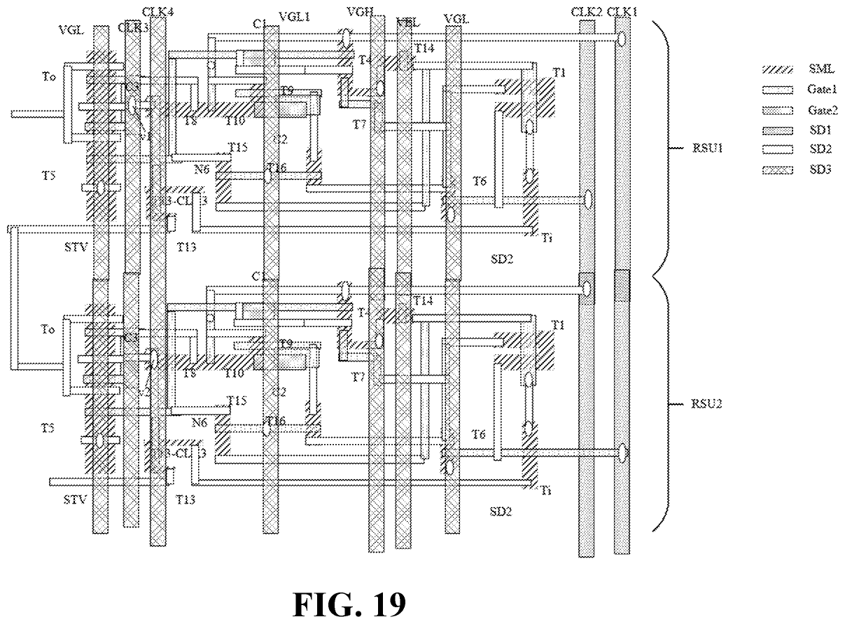

FIG. 19 is a schematic diagram illustrating the structure of various layers of a respective scan unit in some embodiments according to the present disclosure. Referring to FIG. 19, in some embodiments, the scan circuit includes a first adjacent scan unit RSU1 and a second scan unit RSU2 connected to each other. The scan circuit in some embodiments includes a first clock terminal CLK1, a second clock terminal CLK2, a third clock terminal CLK3, and a fourth clock terminal CLK4. Optionally, the first clock terminal CLK1, the second clock terminal CLK2 are in the first signal line layer SD1. Optionally, the third clock terminal CLK3 and the fourth clock terminal CLK4 are in the third signal line layer SD3.

In some embodiments, a first electrode of the output transistor To and a gate electrode of the thirteenth transistor T13 in the first adjacent scan unit RSU1 are connected to the third clock terminal CLK3; and a first electrode of the output transistor To and a gate electrode of the thirteenth transistor T13 in the second adjacent scan unit RSU2 are connected to the fourth clock terminal CLK4.

In some embodiments, the first electrode of the output transistor To and the gate electrode of the thirteenth transistor T13 in the first adjacent scan unit RSU1 are connected to the third clock terminal CLK3 through a first via v1; and the first electrode of the output transistor To and the gate electrode of the thirteenth transistor T13 in the second adjacent scan unit RSU2 are connected to the fourth clock terminal CLK4 through a second via v2.

In some embodiments, an orthographic projection of the first via v1 on a base substrate at least partially overlaps with an orthographic projection of a third capacitor C3 in the first adjacent scan unit RSU1 on the base substrate; and an orthographic projection of the second via v2 on the base substrate is non-overlapping with an orthographic projection of a third capacitor C3 in the second adjacent scan unit RSU2 on the base substrate.

In some embodiments, the third clock terminal CLK3 includes a second electrode of the third capacitor C3 in the first adjacent scan unit RSU1, and a second electrode of the third capacitor C3 in the second adjacent scan unit RSU2.

In another aspect, the present disclosure provides a display apparatus, comprising the scan circuit described herein, and a display panel connected to the scan circuit. Examples of appropriate display apparatuses include, but are not limited to, an electronic paper, a mobile phone, a tablet computer, a television, a monitor, a notebook computer, a digital album, a GPS, etc. Optionally, the display apparatus is a liquid crystal display apparatus. Optionally, the display apparatus is an organic light emitting diode apparatus. Optionally, the display apparatus is a mini light emitting diode apparatus. Optionally, the display apparatus is a micro light emitting diode apparatus.

In another aspect, the present disclosure provides a method of fabricating a scan circuit. In some embodiments, the method includes forming a plurality of scan units cascaded. Optionally, forming a respective scan unit of the plurality of scan units comprises forming a first subcircuit connected to a first node; forming a second subcircuit connected to the first node and a second node; forming a third subcircuit connected to the second node and a third node; forming a fourth subcircuit connected to a fourth node and a sixth node; and forming a fifth subcircuit configured to output an output signal through an output terminal, and is connected to the fourth node. Optionally, forming the first subcircuit comprises forming an input transistor and forming a thirteenth transistor. Optionally, a gate electrode of the thirteenth transistor is configured to receive a third clock signal from a third clock terminal. Optionally, a first electrode of the thirteenth transistor is configured to receive an input signal from an input terminal. Optionally, a second electrode of the thirteenth transistor is connected to a first electrode of the input transistor. Optionally, a gate electrode of the input transistor is configured to receive a second clock signal from a second clock terminal. Optionally, a first electrode of the input transistor is connected to the second electrode of the thirteenth transistor. Optionally, a second electrode of the input transistor is connected to the first node.

In another aspect, the present disclosure provides a method of operating a scan circuit. In some embodiments, the scan circuit includes a plurality of scan units cascaded. In some embodiments, a respective scan unit of the plurality of scan units includes a first subcircuit connected to a first node; a second subcircuit connected to the first node and a second node; a third subcircuit connected to the second node and a third node; a fourth subcircuit connected to a fourth node and a sixth node; and a fifth subcircuit connected to the fourth node. Optionally, the first subcircuit includes an input transistor, a thirteenth transistor, and a fourteenth transistor. In some embodiments, the method includes providing a third clock signal from a third clock terminal to a gate electrode of the thirteenth transistor; providing an input signal from an input terminal to a first electrode of the thirteenth transistor; connecting a second electrode of the thirteenth transistor to a first electrode of the input transistor; connecting a first electrode of the input transistor to the second electrode of the thirteenth transistor; connecting a second electrode of the input transistor to the first node; connecting a second electrode of the fourteenth transistor to the first node; providing a second clock signal from a second clock terminal to a gate electrode of the input transistor; providing an enabling control signal to a gate electrode of the fourteenth transistor; providing a second reference voltage signal from a second reference voltage terminal to a first electrode of the fourteenth transistor; and outputting output signal through an output terminal in the fifth subcircuit.

The foregoing description of the embodiments of the invention has been presented for purposes of illustration and description. It is not intended to be exhaustive or to limit the invention to the precise form or to exemplary embodiments disclosed. Accordingly, the foregoing description should be regarded as illustrative rather than restrictive. Obviously, many modifications and variations will be apparent to practitioners skilled in this art. The embodiments are chosen and described in order to explain the principles of the invention and its best mode practical application, thereby to enable persons skilled in the art to understand the invention for various embodiments and with various modifications as are suited to the particular use or implementation contemplated. It is intended that the scope of the invention be defined by the claims appended hereto and their equivalents in which all terms are meant in their broadest reasonable sense unless otherwise indicated. Therefore, the term “the invention”, “the present invention” or the like does not necessarily limit the claim scope to a specific embodiment, and the reference to exemplary embodiments of the invention does not imply a limitation on the invention, and no such limitation is to be inferred. The invention is limited only by the spirit and scope of the appended claims. Moreover, these claims may refer to use “first”, “second”, etc. following with noun or element. Such terms should be understood as a nomenclature and should not be construed as giving the limitation on the number of the elements modified by such nomenclature unless specific number has been given. Any advantages and benefits described may not apply to all embodiments of the invention. It should be appreciated that variations may be made in the embodiments described by persons skilled in the art without departing from the scope of the present invention as defined by the following claims. Moreover, no element and component in the present disclosure is intended to be dedicated to the public regardless of whether the element or component is explicitly recited in the following claims.

What is claimed is:

1. A scan circuit, comprising a plurality of scan units cascaded;
wherein a respective scan unit of the plurality of scan units comprises:
a first subcircuit connected to a first node;
a second subcircuit connected to the first node and a second node;
a third subcircuit connected to the second node and a third node;
a fourth subcircuit connected to a fourth node and a sixth node; and
a fifth subcircuit configured to output an output signal through an output terminal, and is connected to the fourth node;
wherein the first subcircuit comprises an input transistor, a thirteenth transistor, and a fourteenth transistor;
wherein a gate electrode of the thirteenth transistor is configured to receive a third clock signal from a third clock terminal;
a first electrode of the thirteenth transistor is configured to receive an input signal from an input terminal;
a second electrode of the thirteenth transistor is connected to a first electrode of the input transistor;
a gate electrode of the input transistor is configured to receive a second clock signal from a second clock terminal;
a first electrode of the input transistor is connected to the second electrode of the thirteenth transistor;
a second electrode of the input transistor is connected to the first node;
a gate electrode of the fourteenth transistor is configured to receive an enabling control signal;
a first electrode of the fourteenth transistor is configured to receive a second reference voltage signal from a second reference voltage terminal; and
a second electrode of the fourteenth transistor is connected to the first node.

2. The scan circuit of claim 1, wherein the first subcircuit further comprises a fifteenth transistor;
wherein a gate electrode of the fifteenth transistor is configured to receive a fourth reference voltage signal from a fourth reference voltage terminal;
a first electrode of the fifteenth transistor is connected to the first node; and
a second electrode of the fifteenth transistor is connected to the sixth node.

3. The scan circuit of claim 1, wherein the first subcircuit further comprises a second input transistor and an eighteenth transistor;
wherein a gate electrode of the eighteenth transistor is configured to receive a third clock signal from a third clock terminal, a first electrode of the eighteenth transistor is configured to receive an input signal from an input terminal, a second electrode of the eighteenth transistor is connected to a first electrode of the second input transistor; and
a gate electrode of the second input transistor is configured to receive a second clock signal from a second clock terminal, a first electrode of the second input transistor is connected to a second electrode of the eighteenth transistor, a second electrode of the second input transistor is connected to a sixth node.

4. The scan circuit of claim 1, wherein the second subcircuit comprises a first transistor, a fourth transistor, a seventh transistor, and a first capacitor;
wherein a gate electrode of the first transistor is connected to the first node, a first electrode of the first transistor is configured to receive the second clock signal from the second clock terminal, a second electrode of the first transistor is connected to a second node;
a gate electrode of the fourth transistor is connected to the first node, a first electrode of the fourth transistor is configured to receive a first clock signal from a first clock terminal, a second electrode of the fourth transistor is connected to a fifth node;
a gate electrode of the seventh transistor is connected to the second node, a first electrode of the seventh transistor is configured to receive the second reference voltage signal from the second reference voltage terminal, a second electrode of the seventh transistor is connected to the fifth node; and
a first electrode of the first capacitor is connected to the first node, a second electrode of the first capacitor is connected to the fifth node.

5. The scan circuit of claim 1, wherein the third subcircuit comprises a sixth transistor, a ninth transistor, a tenth transistor, and a second capacitor;
wherein a gate electrode of the sixth transistor is configured to receive the third clock signal from the third clock terminal, a first electrode of the sixth transistor is configured to receive a third reference voltage signal from a third reference voltage terminal, a second electrode of the sixth transistor is connected to the second node;
a gate electrode of the ninth transistor is connected to the second node, a first electrode of the ninth transistor is configured to receive the first clock signal from the first clock terminal, a second electrode of the ninth transistor is connected to a third node;
a gate electrode of the tenth transistor is configured to receive the first clock signal from the first clock terminal, a first electrode of the tenth transistor is connected to the third node, a second electrode of the tenth transistor is connected to a fourth node; and
a first electrode of the second capacitor is connected to the second node, a second electrode of the second capacitor is connected to the third node.

6. The scan circuit of claim 1, wherein the third subcircuit comprises a sixth transistor, a ninth transistor, a tenth transistor, a sixteenth transistor, and a second capacitor;
wherein a gate electrode of the sixth transistor is configured to receive the third clock signal from the third clock terminal, a first electrode of the sixth transistor is configured to receive a third reference voltage signal from a third reference voltage terminal, a second electrode of the sixth transistor is connected to a first electrode of the sixteenth transistor;
a gate electrode of the sixteenth transistor is configured to receive the fourth reference voltage signal from the fourth reference voltage terminal, a first electrode of the sixteenth transistor is connected to the second electrode of the sixth transistor, a second electrode of the sixteenth transistor is connected to the second node;
a gate electrode of the ninth transistor is connected to the second node, a first electrode of the ninth transistor is configured to receive the first clock signal from the first clock terminal, a second electrode of the ninth transistor is connected to a third node;
a gate electrode of the tenth transistor is configured to receive the first clock signal from the first clock terminal, a first electrode of the tenth transistor is connected to the third node, a second electrode of the tenth transistor is connected to a fourth node; and
a first electrode of the second capacitor is connected to the second node, a second electrode of the second capacitor is connected to the third node.

7. The scan circuit of claim 1, wherein the third subcircuit comprises a sixth transistor, a ninth transistor, a tenth transistor, a sixteenth transistor, and a second capacitor;
wherein a gate electrode of the sixth transistor is configured to receive the third clock signal from the third clock terminal, a first electrode of the sixth transistor is configured to receive a third reference voltage signal from a third reference voltage terminal, a second electrode of the sixth transistor is connected to a first electrode of the sixteenth transistor;
a gate electrode of the sixteenth transistor is configured to receive the second clock signal from the second clock terminal, a first electrode of the sixteenth transistor is connected to the second electrode of the sixth transistor, a second electrode of the sixteenth transistor is connected to the second node;
a gate electrode of the ninth transistor is connected to the second node, a first electrode of the ninth transistor is configured to receive the first clock signal from the first clock terminal, a second electrode of the ninth transistor is connected to a third node;
a gate electrode of the tenth transistor is configured to receive the first clock signal from the first clock terminal, a first electrode of the tenth transistor is connected to the third node, a second electrode of the tenth transistor is connected to a fourth node; and
a first electrode of the second capacitor is connected to the second node, a second electrode of the second capacitor is connected to the third node.

8. The scan circuit of claim 1, wherein the fourth subcircuit comprises a fifth transistor, an eighth transistor, and a fourth capacitor;
wherein a gate electrode of the fifth transistor is connected to a sixth node, a first electrode of the fifth transistor is configured to receive the third reference voltage signal from the third reference voltage terminal, a second electrode of the fifth transistor is connected to an output terminal;
a gate electrode of the eighth transistor is connected to a sixth node, a first electrode of the eighth transistor is configured to receive the third clock signal from the third clock terminal, a second electrode of the eighth transistor is connected to the fourth node; and
a first electrode of the fourth capacitor is configured to receive the third reference voltage signal from the third reference voltage terminal, a second electrode of the fourth capacitor is connected to the sixth node.

9. The scan circuit of claim 1, wherein the fourth subcircuit comprises a fifth transistor, an eighth transistor, an eleventh transistor, a seventeenth transistor, and a fourth capacitor;
wherein a gate electrode of the fifth transistor is connected to a sixth node, a first electrode of the fifth transistor is configured to receive the third reference voltage signal from the third reference voltage terminal, a second electrode of the fifth transistor is connected to an output terminal;
a gate electrode of the eighth transistor is connected to a sixth node, a first electrode of the eighth transistor is configured to receive the third clock signal from the third clock terminal, a second electrode of the eighth transistor is connected to the fourth node;
a first electrode of the fourth capacitor is configured to receive the third reference voltage signal from the third reference voltage terminal, a second electrode of the fourth capacitor is connected to the sixth node;
a gate electrode of the eleventh transistor is configured to receive an enabling control signal, a first electrode of the eleventh transistor is configured to receive a first reference voltage signal from a first reference voltage terminal, a second electrode of the eleventh transistor is connected to the sixth node; and
a gate electrode and a first electrode of the seventeenth transistor are connected to the first node, a second electrode of the seventeenth transistor is connected to the sixth node.

10. The scan circuit of claim 1, wherein the fifth subcircuit comprises an output transistor and a third capacitor;
wherein a gate electrode of the output transistor is connected to the fourth node, a first electrode of the output transistor is configured to receive the first reference voltage signal from the first reference voltage terminal, a second electrode of the output transistor is connected to the output terminal; and
a first electrode of the third capacitor is connected to the fourth node, a second electrode of the third capacitor is configured to receive the first reference voltage signal from the first reference voltage terminal.

11. The scan circuit of claim 1, wherein an orthographic projection of the third clock terminal on a base substrate spaces apart an orthographic projection the output transistor and the fifth transistor on the base substrate from an orthographic projection of capacitors and transistors other than the output transistor and the fifth transistor on the base substrate; and
the orthographic projection of capacitors and transistors other than the output transistor and the fifth transistor on the base substrate is between the orthographic projection of the third clock terminal on the base substrate and an orthographic projection of the second clock terminal on the base substrate.

12. The scan circuit of claim 11, wherein a gate electrode of a sixth transistor in the third subcircuit is connected to the second clock terminal; and
gate electrodes of the sixth transistor and the input transistor are parts of a unitary structure.

13. The scan circuit of claim 11, wherein a gate electrode of a sixth transistor in the third subcircuit is connected to the third clock terminal;
gate electrodes of the sixth transistor and the thirteenth transistor are connected to each other through a gate connecting line; and
an orthographic projection of the gate connecting line on the base substrate at least partially overlaps with an orthographic projection of at least one of a first reference voltage terminal or a fourth reference voltage terminal on the base substrate.

14. The scan circuit of claim 11, wherein the respective scan unit comprises a first gate pad comprising a gate electrode of the thirteenth transistor, a second gate pad comprising a gate electrode of a fifth transistor in the fourth subcircuit, and a clock connecting line connecting the first gate pad to the third clock terminal and to a first electrode of an eighth transistor in the fourth subcircuit; and
an orthographic projection of the clock connecting line on the base substrate partially overlaps with an orthographic projection of the second gate pad on the base substrate.

15. The scan circuit of claim 11, wherein the respective scan unit comprises a first gate pad comprising a gate electrode of the thirteenth transistor, a second gate pad comprising a gate electrode of a fifth transistor in the fourth subcircuit, and a clock connecting line connecting the first gate pad to a first electrode of an eighth transistor in the fourth subcircuit;
a shortest distance between the thirteenth transistor and a fifth transistor in the fourth subcircuit is greater than a shortest distance between the thirteenth transistor and an output transistor in the fifth subcircuit; and
an orthographic projection of the clock connecting line on the base substrate is non-overlapping with an orthographic projection of the second gate pad on the base substrate.

16. The scan circuit of claim 11, wherein the respective scan unit comprises a first gate pad comprising a gate electrode of the thirteenth transistor, a second gate pad comprising a gate electrode of a fifth transistor in the fourth subcircuit, a first clock connecting line connecting a first electrode of an eighth transistor in the fourth subcircuit to the third clock terminal, and a second clock connecting line connecting the first gate pad to the third clock terminal;
an orthographic projection of the first clock connecting line on the base substrate is non-overlapping with an orthographic projection of the second gate pad on the base substrate;
an orthographic projection of the second clock connecting line on the base substrate is non-overlapping with the orthographic projection of the second gate pad on the base substrate; and
the orthographic projection of the second gate pad on the base substrate spaces apart the orthographic projection of the first clock connecting line on the base substrate from the orthographic projection of the second clock connecting line on the base substrate.

17. The scan circuit of claim 11, wherein the third clock terminal extends along a first direction;
the third clock terminal, the second clock terminal, and the first clock terminal are arranged along a second direction; and
an orthographic projection, along the second direction, of an active layer of a fifth transistor in the fourth subcircuit on a plane perpendicular to a semiconductor material layer, a first gate metal layer, a second gate metal layer, a first signal line layer, a second signal line layer, and a third signal line layer covers an orthographic projection, along the second direction, of an active layer of the thirteenth transistor on the plane perpendicular to the semiconductor material layer, the first gate metal layer, the second gate metal layer, the first signal line layer, the second signal line layer, and the third signal line layer.

18. The scan circuit of claim 1, comprising a first adjacent scan unit and a second adjacent scan unit connected to each other;
wherein the scan circuit further comprises a fourth clock terminal;
a first electrode of an output transistor in the fifth subcircuit and a gate electrode of the thirteenth transistor in the first adjacent scan unit are connected to the third clock terminal through a first via;
a first electrode of an output transistor in the fifth subcircuit and a gate electrode of the thirteenth transistor in the second adjacent scan unit are connected to the fourth clock terminal through a second via;
an orthographic projection of the first via on a base substrate at least partially overlaps with an orthographic projection of a third capacitor in the first adjacent scan unit on the base substrate; and an orthographic projection of the second via on the base substrate is non-overlapping with an orthographic projection of a third capacitor in the second adjacent scan unit on the base substrate; and
the third clock terminal comprise a second electrode of the third capacitor in the first adjacent scan unit, and a second electrode of the third capacitor in the second adjacent scan unit.

19. A display apparatus, comprising the scan circuit of claim 1, and a display panel connected to the scan circuit.

20. A method of operating a scan circuit;
wherein the scan circuit includes a plurality of scan units cascaded;
wherein a respective scan unit of the plurality of scan units includes a first subcircuit connected to a first node; a second subcircuit connected to the first node and a second node; a third subcircuit connected to the second node and a third node; a fourth subcircuit connected to a fourth node and a sixth node; and a fifth subcircuit connected to the fourth node;
wherein the first subcircuit includes an input transistor, a thirteenth transistor, and a fourteenth transistor;
wherein the method comprises:
providing a third clock signal from a third clock terminal to a gate electrode of the thirteenth transistor;
providing an input signal from an input terminal to a first electrode of the thirteenth transistor;
connecting a second electrode of the thirteenth transistor to a first electrode of the input transistor;
connecting a first electrode of the input transistor to the second electrode of the thirteenth transistor;
connecting a second electrode of the input transistor to the first node;
connecting a second electrode of the fourteenth transistor to the first node;
providing a second clock signal from a second clock terminal to a gate electrode of the input transistor;
providing an enabling control signal to a gate electrode of the fourteenth transistor;
providing a second reference voltage signal from a second reference voltage terminal to a first electrode of the fourteenth transistor; and
outputting output signal through an output terminal in the fifth subcircuit.
